(19) United States
(12) Patent Application Publication
(10) Pub. No.: US 2019/0227751 A1
(43) Pub. Date: Jul. 25, 2019

(54) STORAGE SYSTEM WITH RECONFIGURABLE NUMBER OF BITS PER CELL

(71) Applicant: Intel Corporation, Santa Clara, CA (US)

(72) Inventors: Ali KHAKIFIROOZ, Los Altos, CA (US); Pranav KALAVADE, San Jose, CA (US); Xin GUO, San Jose, CA (US); Aliasgar S. MADRASWALA, Folsom, CA (US); Bharat M. PATHAK, Folsom, CA (US)

(21) Appl. No.: 16/370,743

(22) Filed: Mar. 29, 2019

(51) Int. Cl. G06F 3/06; G11C 11/56; G11C 16/10

(52) U.S. Cl. CPC G06F 3/0659; G06F 3/0604; G11C 16/0483; G11C 11/56; G11C 16/10; G06F 3/0679

(57) ABSTRACT

A memory device is designed to store data in multilevel storage cells (MLC storage cells). The memory device includes a controller that dynamically writes data to the storage cells according to a first MLC density or a second MLC density. The second density is less dense than the first density. For example, the controller can determine to use the first density when there is sufficient write bandwidth to program the storage cells at the first density. When the write throughput increases, the controller can program the same MLC storage cells at the second density instead of the first density, using the same program process and voltage.

### FIELD

Descriptions are generally related to storage devices, and more particular descriptions relate to a storage system with a dynamically changeable number of bits per cell.

### BACKGROUND

There is pressure on storage device manufacturers to increase the total amount of storage available in emerging devices. However, the form factors for the storage continues to shrink as devices have reductions in either planar footprint or in thickness, or both. To provide increased storage in smaller form factors, storage device manufacturers have worked on increasing the density in storage devices.

One mechanism to increase density it to create storage devices with more bits. Another mechanism is to apply technologies that allow a higher number of bits per cell. When using bitcells that can store multiple bits, there is a tradeoff between density and performance. Namely, bitcells with higher density take much longer to program. Typically, the programming timing is not linear, but rather increases exponentially with the increased number of bits per cell. The programming has traditionally been required to be significantly slower to ensure the accuracy needed for when dealing with the finer voltage level differences, and the increased number of verify operations needed to ensure a correct data write occurs.

Traditional storage devices perform different program operations, depending on the density of the number of bits per cell. A storage controller would traditionally have separate program algorithms with all the parameters needed to control the separate algorithms.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system that selectively stores data between different densities of multilevel cells.

FIG. 2 is a block diagram of an example of a storage device that can store data selectively as quad level cells, trilevel cells, or two level cells.

FIG. 3 is a diagram of an example of threshold voltage distribution for TLC cells.

FIG. 4 is a diagram of an example of threshold voltage distribution for TLC cells with a 2-pass 2-8 programming sequence.

FIG. 5 is a diagram of an example of threshold voltage distribution for QLC cells.

FIG. 6 is a diagram of an example of threshold voltage distribution for QLC cells with a 2-pass 4-16 programming sequence.

FIG. 7 is a diagram of an example of threshold voltage distribution for QLC cells with a 3-pass 2-8-16 programming sequence.

FIG. 8 is a diagram of an example of a program waveform for a QLC NAND.

FIG. 9 is a flow diagram of an example of a program sequence for either QLC or two level cell based on a 4-16 programming sequence.

FIG. 10 is a flow diagram of an example of a program sequence for either QLC or TLC with a 2-8-16 program sequence.

FIG. 11 is a diagram of an example of threshold voltage distribution for a 4-8 programming sequence of TLC cells based on a 4-16 program sequence for QLC cells.

FIG. 12A is a diagram of an example of a 1-2-4-8 Gray code for QLC level assignment.

FIG. 12B is a diagram of an example of a 1-2-6-6 Gray code for QLC level assignment.

FIG. 13 is a flow diagram of an example of a program sequence to implement either a 4-16 QLC program or 4-8 TLC program.

FIG. 14 is a diagram of an example of threshold voltage distribution for a 2-8 program sequence of TLC cells based on a 4-16 program sequence for QLC cells.

FIG. 15 is a flow diagram of an example of a program process to implement a 2-8 TLC program based on a 4-16 QLC program algorithm.

FIG. 16 is a flow diagram of an example of a program process to implement a 2-8 TLC program based on a 4-16 QLC program algorithm as an alternative to FIG. 15.

FIG. 17 is a flow diagram of an example of a program process to implement either a QLC program or a 2LC program based on a 2-8-16 QLC algorithm.

FIG. 18 is a block diagram of an example of a computing system in which a storage device selectively that stores data at either one multilevel cell density or another multilevel cell density can be implemented.

FIG. 19 is a block diagram of an example of a mobile device in which a storage device selectively that stores data at either one multilevel cell density or another multilevel cell density can be implemented.

Descriptions of certain details and implementations follow, including non-limiting descriptions of the figures, which may depict some or all examples, and well as other potential implementations.

### DETAILED DESCRIPTION

As described herein, a storage system is dynamically reconfigurable to use one density of multilevel bitcells or another density of multilevel bitcells. For example, the system could support QLC (quad level cells) and TLC (trilevel cells), or QLC and double level cells. For purposes herein, MLC (multilevel cells) refers to a storage cell or bitcell that stores more than one bit of data. Thus, a single addressable storage location can hold multiple bits of data. MLC can be QLC, TLC, or double level cells (which can also be referred to as two-level cells). Reference to a bitcell, memory unit, or storage cell can refer to an addressable storage location with the memory system.

A memory device is designed to store data in multilevel storage cells (MLC storage cells), and typically supports a first, denser bit density. The memory device includes a controller that dynamically writes data to the storage cells according to the first MLC density or a second MLC density less dense than the first density. Thus, the storage system can switch from MLC to MLC, with different densities. The lower density mode can be programmed with a programming sequence shared with the higher density mode, with modifications to the sequence. The modifications to the sequence can include one or more configuration changes, and the elimination of one or more passes or levels of programming. Thus, the storage controller can perform the same program sequence with the same control paths, but result in different MLC densities.

In one example, the storage system is a nonvolatile storage system with solid state NVM (nonvolatile media) to store the data. For example, the system can be based on NAND (not AND) memory units. In one example, the storage system includes a storage controller or memory controller and a plurality of multi-level per cell NAND memory units. As described, the number of bits per cell can be reconfigured on-the-fly and during the active operation of the storage system.

In one example, the different algorithms for storing data, or the swapping between different storage densities within the storage device can be identified with the handshake between the controller and storage device. For example, under different write throughput conditions, the storage device may identify different storage capacities.

In one example, the memory units are designed and configured in the higher number of bits-per-cell configuration. In one example, the lower number of bits per cell configuration is performed by skipping the last programming pass in a multi-pass programming sequence. For example, in a 4-bit-per-cell (QLC) memory unit that uses a 4-16 programming sequence, the controller can achieve a 2-bit-per-cell configuration by skipping the second pass of the programming algorithm. Thus, only the first path (the ‘4’) ends up being programmed, and not the second pass (the ‘16’).

In one example, the programming algorithm is modified to program a smaller number of bits in each pass. For example, in a QLC memory unit that uses a 4-16 programming algorithm, the first pass can be modified to program only one bit per cell, and the second pass modified to program 3 bits per cell, thus reconfiguring the memory unit to a 3-bits-per-cell (TLC) configuration with a 2-8 programming algorithm.

By providing the controller the ability to implement modified programming sequences, either by writing fewer bits per pass, or by eliminating a programming step, or a combination of writing fewer bits and eliminating a programming step, the system can implement a configurable number of bits per cells with much simpler program logic than implementing it with separate programming algorithms. Furthermore, the circuitry required to interface with the memory units can be the same regardless of which programming sequence is used. Such a system enables the application of reconfigurable numbers of bits per cell, whereas an implementation where separate circuitry is provided to implement separate programming algorithms on the same chip or same device would be impractical.

In one example, the controller determines if a higher write throughput is needed to service incoming write requests. In one example, if the controller determines that the write throughput is higher than can be handled by writing to the slower higher density memory units or cells, the controller reconfigures the memory units to operate in a smaller number of bits-per-cell configuration. With a lower number of bits-per-cell, the storage device can program the data faster, improving write throughput. In one example, when higher write throughput is not needed, the controller configures the memory units to operate in a higher number of bits-per cell configuration. The higher number of bits-per-cell configuration enables a higher storage capacity for the same device. Thus, the system can provide higher burst write throughput while maintaining higher storage capacity. The on-the-fly reconfigurability enables the system to respond in realtime to changing write throughput requirements of the host system for which the storage device or storage system stores data.

For example, the controller can determine to use the first density when there is sufficient write bandwidth to program the storage cells at the first density. When the write throughput increases, the controller can program the same MLC storage cells at the second density instead of the first density, using the same program process and voltage. When the write throughput decreases, the controller can program the same MLC storage cells at the first density again.

In one example, when the storage system is idle or otherwise the burst of write throughput reduces sufficiently, the controller can copy back the data from the lower number of bit-per-cell configuration (the lower density cells) to higher number of bits-per-cell configuration (the higher density cells). The time to reconfigure the memory units can be substantially less than the time needed to read the data. As provided in more detail below, an implementation can have minimal area overhead in the NAND die or other storage device.

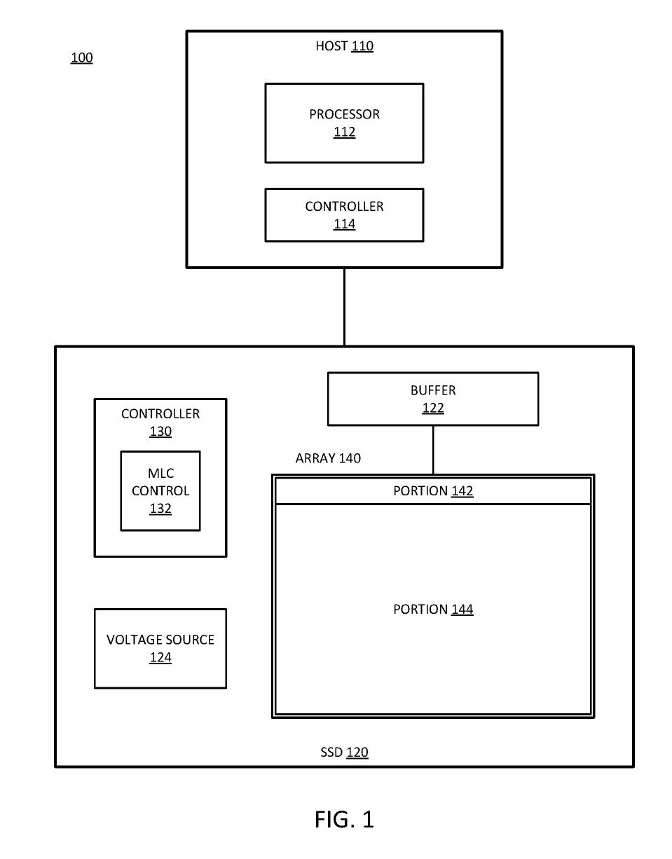

FIG. 1 is a block diagram of an example of a system that selectively stores data between different densities of multilevel cells. System 100 includes SSD 120 coupled with host 110. Host 110 represents a host hardware platform that connects to SSD 120. Host 110 represents a system for which SSD 120 stores data. SSD 120 can be or include a storage system.

Host 110 includes CPU (central processing unit) 112 or other processor as a host processor. CPU 112 represents any host processor that generates requests to access data stored on 120, either to read the data or to write data to the storage. Such a processor can include a single or multicore processor, a primary processor for a computing device, a graphics processor, a peripheral processor, or a supplemental or auxiliary processor, or a combination. CPU 112 can execute a host OS and other applications to cause the operation of system 100.

Host 110 includes controller 114, which represents hardware components that can be included in connecting between CPU 112 and SSD 120. Controller 114 can include interconnect circuits and logic to enable access to SSD 120. Controller 114 represents a system controller or host side controller, and will be understood to be different from controller 130 within SSD 120.

SSD 120 represents a solid state drive that stores data in a nonvolatile media (NVM) array. Array 140 represents the NVM array. In one example, array 140 includes QLC flash memory. The flash memory can include NAND storage cells, NOR storage cells, or other storage. In one example, all or a portion of array 140 is reconfigurable as TLC flash memory. In one example, all or a portion of array 140 is reconfigurable as two level flash memory.

For example, consider that host 110 generates a sequence of writes to SSD 120 that will result in a higher write throughput than controller 130 can store to array 140 in a given time window. In one example, controller 130 configures portion 142 of array 140 as a less dense storage area, while portion 144 remains unaffected. In such an example, reconfiguring can refer to allocation by controller 130 of portion 142 to store data at a lower density than portion 144. When data is stored to portion 142, the data is stored in accordance with a different program sequence to result in storage at a different density or bits per cell than the density of portion 144. Portion 142 is not necessarily at any specific area of array 140. In one example, portion 142 includes address space scattered throughout array 140, rather than being contiguous address space. Portion 144 can also be subject to store data at lower density when controller 130 configures a storage algorithm or process to program the cells in accordance with a lower density.

SSD 120 includes controller 130 to control access to array 140. Controller 130 represents hardware and control logic within SSD 120 to execute control over the media, including control of the number of bits per cell each storage address is to store. MLC control 132 represents logic within controller 130 to provide reconfigurable control over array 140. The reconfigurable control can be in accordance with any example herein, including switching between QLC and TLC, or QLC and some other MLC.

SSD 120 is illustrated to include buffer 122. Buffer 122 represents a buffer for an access interface between array 140 and controller 114. Buffer 122 includes memory that has faster access time than array 140. For example, buffer 122 can include SLC (single level cell) storage, byte-addressable nonvolatile storage devices such as resistive based memory that stores data based on a resistance at an address location, a dynamic random access memory (DRAM) device, or other memory. It will be understood that buffer 122 is separate from portion 142 or the portion of array 140 that is reconfigured to store at a lower density. With dynamically reconfigurable storage, buffer 122 may be reduced in size relative to other storage systems, or eliminated, depending on the system configuration.

SSD 120 includes voltage source 124, which represents a voltage source within SSD 120 to provide program voltages to array 140. In one example, SSD 120 receives one or more voltages from host 110. Typically, SSD 120 includes one or more voltage regulators or voltage pumps to provide different voltages to use for program and verify operations. The voltages are changed dynamically through the program and verify sequences, based on control by controller 130. In one example, the voltage used are the same for lower density and higher density storage. In one example, the voltages are different when configured for a lower density mode versus the default higher density mode. In one example, controller 130 configures the voltages of voltage source 124 differently, depending on control from MLC control 132. Thus, controller 130 can cause the use of different voltage sequences for an area configured as a lower density storage area, represented as portion 142, versus portion 144, which represents a storage area at highest storage density.

It will be understood that in one example, portion 142 will only exist during conditions of higher write throughput. For example, array 140 may typically only include storage of the type of portion 144, but controller 130 can configure portion 142 while needed. After the need for a faster write is past, in one example, controller 130 writes the data of portion 142 back to higher density storage, and eliminates portion 142.

In one example, MLC control 132 includes a common programming algorithm for multiple different MLC states or MLC modes. In one example, the programming algorithm has variations that account for the different number of bits per cell, but are otherwise the same algorithm. In one example, controller 130 programs cells of portion 142 with a common voltage to cells of portion 144, even when different storage densities are used. In one example, the program pulse width is different for storing between different modes, where different modes have different numbers of bits per cell.

In general, to improve write throughput while still benefiting from higher storage capacity, a storage system has a reconfigurable number of bits per cell. in one example, the system includes a storage or memory controller and a plurality of QLC nonvolatile memory units, such as QLC NAND units. The storage controller can be coupled to the host and the plurality of nonvolatile memory units. The storage controller can be referred to as a NAND controller when it is associated with a NAND die. The SSD can include multiple NAND dies and multiple NAND controllers. In one example, the controller connects to a volatile memory such as a DRAM or SRAM to temporarily store data and address lookup tables. In a system with multiple nonvolatile memory devices, in one example, each nonvolatile memory has a controller and storage locations.

In one example, the storage controller is capable of determining the workload for write throughput based on the requests it receives from the host. When the storage controller determines that a workload requested has a higher write throughput than can be achieved from a default configuration of the storage (e. g., QLC configuration), the storage controller sends a series of commands to at least one of the NAND units to reconfigure the selected unit or units to a lower number of bits-per-cell configuration, such as a TLC configuration or two-level-cell configuration. For subsequent program or read commands received for the NAND units, the storage controller executes the commands to access the unit in TLC mode. In one example, the storage controller sends a set of commands to the NAND units to reconfigure them back to QLC mode when the workload has reduced.

In one example, the storage controller maintains a list of addresses, such as a list of blocks, that are programmed in a lower density mode to enable reconfiguration of the commands for read operations. In one example, a subset of blocks from each NAND unit is statically assigned to be configured in the lower number of bits per cell. In such an implementation, the number of lower density blocks can be kept small. In such an implementation, lower density blocks may require significantly higher endurance capability compared to higher density blocks, given that for each erase/program cycle experienced by higher density blocks, the lower density blocks undergo a significantly higher number of erase/program cycles. In one example, a subset of blocks from each NAND unit is dynamically assigned to be configured in the lower number of bits per cell. In such an implementation, the number of lower density blocks can be larger if needed. In such an implementation, lower density blocks do not require higher endurance capability compared to higher density blocks, because each block on average experiences the same number of erase/program cycles.

In one example, the NAND controller maintains parameters to operate both higher density and lower density blocks. The parameters can include settings that control the erase condition, program pulse steps (ΔV_{PGM}), program verify (PV), read references (R), or other settings. In one example, each block is assigned dynamically to be either a lower density block or a higher density block, such as a TLC or QLC block. Such operation can ensure that each block on average will undergo the same number of erase/program cycles. In one example, the NAND controller may share some of the parameters that control erase, program, or read operations between lower density and higher density modes. Sharing parameters can reduce the number of storage locations on each die needed to maintain these parameters.

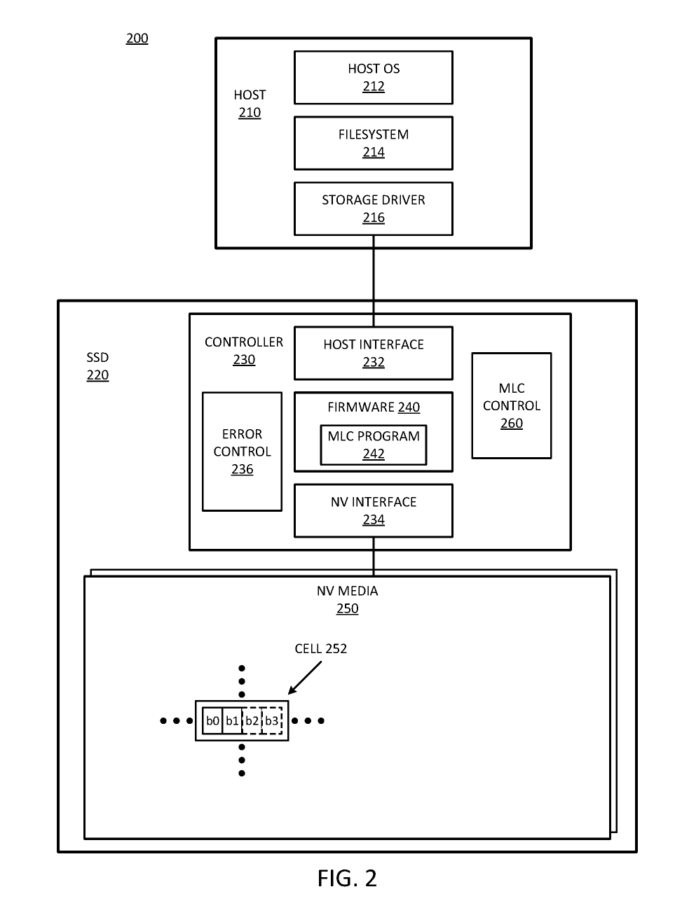

FIG. 2 is a block diagram of an example of a storage device that can store data selectively as quad level cells, trilevel cells, or two level cells. System 200 provides one example of a system in accordance with system 100 of FIG. 1. System 200 illustrates the logical layers of a host and SSD of a hardware platform, which can be in accordance with system 100. In one example, host 210 provides one example of host 110. In one example, SSD 220 provides one example of SSD 120.

In one example, host 210 includes host OS 212, which represents a host operating system or software platform for the host. Host OS 212 can include a platform on which applications, services, agents, other software executes, and is executed by a processor. Filesystem 214 represents control logic for controlling access to the NV media. Filesystem 214 can manage what addresses or memory locations are used to store what data. There are numerous filesystems known, and filesystem 214 can implement known filesystems or other proprietary systems. In one example, filesystem 214 is part of host OS 212.

Storage driver 216 represents one or more system-level modules that control the hardware of host 210. In one example, drivers 216 include a software application to control the interface to SSD 220, and thus control the hardware of SSD 220. Storage driver 216 can provide a communication interface between the host and the SSD.

Controller 230 of SSD 220 includes firmware 240, which represents control software/firmware for the controller. In one example, controller 230 includes host interface 232, which represents an interface to host 210. In one example, controller 230 includes NV interface 234, which represents an interface to NV media device(s) 250. Interfaces 232 and 234 represent control that is executed on hardware of controller 230. It will be understood that controller 230 includes hardware to interface with host 210, which can be considered to be controlled by host interface software/firmware 232. Likewise, it will be understood that controller 230 includes hardware to interface with NV media 250. In one example, code for host interface 232 can be part of firmware 240. In one example, code for NV interface 234 can be part of firmware 240.

Firmware 240 controls the hardware interfaces to enable communication. The control can include providing configuration settings and performing communication operations, such as supporting a communication stack. In one example, one or more interfaces within system 200 comply with a standard such as PCIe (such as peripheral component interconnect express 4.0, released June 2017, available from the PCI Special Interest Group (PCI-SIG)), NVMe (such as nonvolatile memory express 1.3c, released May 2018, available from NVM Express, Inc.), or other nonvolatile memory interconnection standard, or other versions/releases, or derivatives.

In one example, controller 230 includes error control 236. Error control 236 handles data errors in accessed data, and corner cases in terms of compliance with signaling and communication interfacing. In one example, some or all of error control 236 is implemented in hardware. In one example, most of error control 236 is implemented in firmware. A firmware implementation can provide improved flexibility and reduced circuitry, although there may be a performance tradeoff relative to an all-hardware implementation.

NV media 250 represents a nonvolatile device in accordance with any example described. NV media 250 includes an array of nonvolatile cells, with cell 252 illustrated as a single example of a cell. In one example, cell 252 can support a QLC implementation. According to what is described herein, cell 252 can be dynamically reconfigured as a TLC or two-level cell. MLC control 260 represents control logic and circuitry to execute such a reconfiguration. In one example, MLC control 260 includes a detection mechanism to cause reconfiguration. For example, MLC control 260 can include a firmware routine of firmware 240 that is triggered in response to detection of a condition in SSD 220. Such a condition could be when a write throughput reaches a threshold level. Any other condition that would benefit from being able to program faster could likewise trigger a dynamic reconfiguration of at least a portion of NV media 250, such as cell 252. In general, MLC control 260 represents control and decision making regarding the changing of one MLC mode to another MLC mode for cell 252 and other cells. In one example, MLC control 260 is part of firmware 240.

MLC program 242 of firmware 240 can represent one or more programming sequences. A programming sequence could also be referred to as a programming algorithm, and represents a series of operations by which controller 230 programs or writes data to NV media 250. Typically, the programming algorithm includes one or more operations to charge and set a target cell, followed by one or more verification operations to ensure the cell was correctly set. In one example, MLC program 242 represents a program sequence for a higher number of bits per cell that can be modified to alternatively program at a lower number of bits per cell.

Cell 252 is represented as having b0 and b1, referring to at least two bits as a minimum condition for cell 252 to be a multilevel cell. In one example, cell 252 can also include b2 as an MSB (most significant bit) for a TLC cell. In one example, cell 252 can also include b3 (and necessarily will also include b2) as the MSB for a QLC cell. Cell 252 can be programmed for any MLC mode with b0 and b1, and alternatively have b0:b2 or b0:b3.

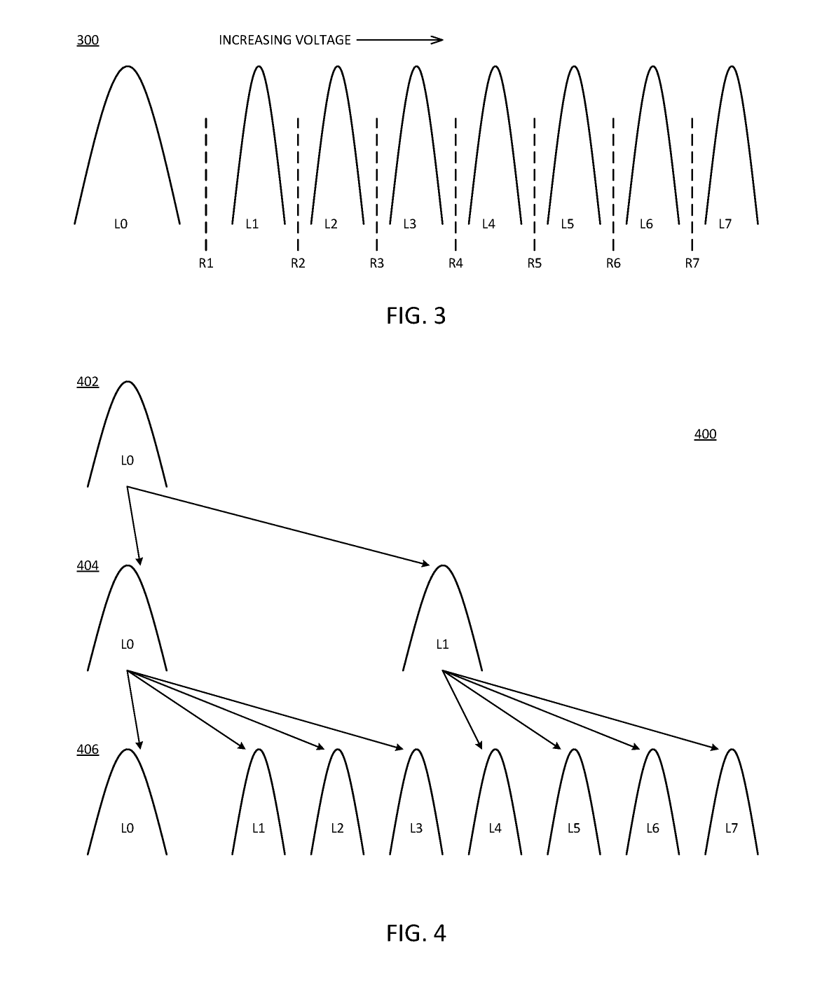

FIG. 3 is a diagram of an example of threshold voltage distribution for TLC cells. Diagram 300 illustrates the voltage distribution of voltage levels L0:L7. In multilevel per cell nonvolatile memories, each memory cell stores more than one bit of information. For example, in a three-level per cell (TLC) NAND memory each memory cell is programmed into one of 8 possible states to store 3 bits of information, with the different state being translated into the three bits.

In one example, during the program operation, three pages of data are provided by the host. Memory cells that belong to the selected wordline (WL) are programmed to one of the 8 possible threshold voltage levels denoted by L0:L7 in diagram 300. In one example, the three pages can be denoted as LP, UP, and XP (respectively, page0, page1, and page2).

In general, an MLC is programmed to one of 2̂N possible states, where N indicates the number of bits to be stored. Typically, multiple cells are accessed concurrently, and thus, the different bits of a cell can be considered part of a page of data that will be accessed as a group of bits. Multiple bits per cell can be bits for different pages. Other organizations and distributions of bits into pages can be performed. For purposes of explanation throughout, it will be assumed that the different bits of a multilevel cell are part of different pages.

To read the information stored in MLC memory such a TLC NAND, the threshold voltage of the cells that belong to the selected WL are compared against a set of reference read voltages, illustrated in diagram 300 as R1:R7. R1 represents a threshold voltage that can distinguish between L0 and L1. R2 represents a threshold voltage between L1 and L2, and so forth. As an example, cells that are not triggered by R3, but are then triggered by R4 can be understood to have the value at L3. As illustrated for diagram 300, voltage increases to the right of the page. Thus, R2 is higher than R1, R3 is higher than R2, and so forth. The increasing voltage is not illustrated on diagrams below, but will be understood to apply to other voltage distribution diagrams.

FIG. 4 is a diagram of an example of threshold voltage distribution for TLC cells with a 2-pass 2-8 programming sequence. Diagram 400 represents a programming sequence for TLC cells. The program sequence of diagram 400 can be applied by a controller that manages the programming of an MLC cell. In one example, the controller performs the sequence of diagram 400 as an alternative to a sequence for a QLC cell.

Programming data in multi-bits-per cell NAND memory or other nonvolatile memory is typically performed in multiple passes to minimize the effect of interference between neighboring cells. The process may apply to other nonvolatile memory, but NAND memory will be used as an example throughout.

As an example, programming a TLC NAND memory may be performed with the 2-pass 2-8 algorithm illustrated. Stage 402 represents the threshold voltage distribution of the cells prior to programming. Stage 404 represents a first pass, where the one page of data is provided, and the memory cells are programmed into one of the two states denoted by L0 and L1. Stage 406 represents the second pass, where two more pages of data are provided, the data already programmed into the cells in stage 404 is read and the cells are programmed into one of the 8 possible states L0:L7. The first pass is thus one of 2 states, and the second pass is one of 8 states, resulting in a 2-8 sequence. The second pass may be performed after the next WL is programmed to its first pass to minimize the interference from neighboring cells.

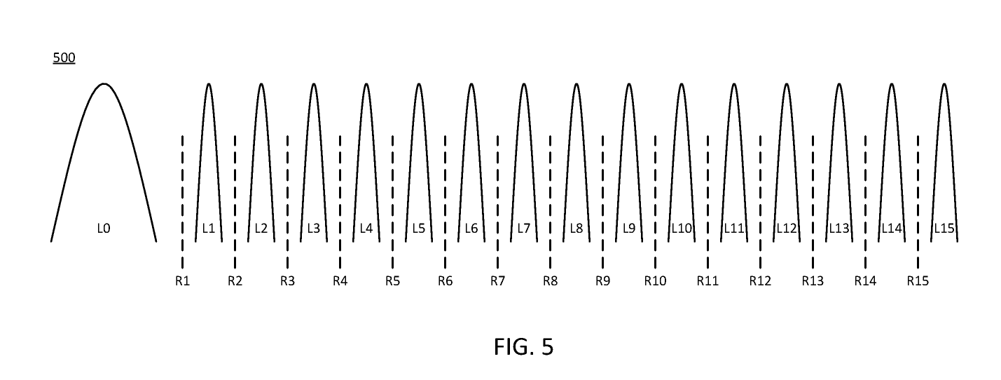

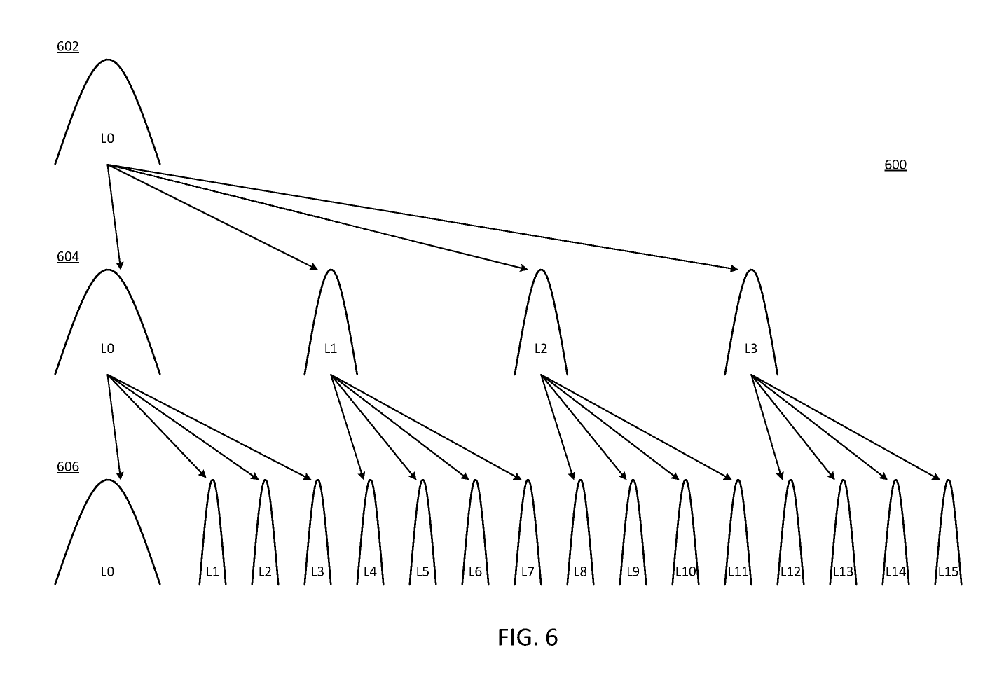

FIG. 5 is a diagram of an example of threshold voltage distribution for QLC cells. Diagram 500 illustrates the voltage distribution of voltage levels L0:L15. The example illustrates a four-level per cell (QLC) NAND memory in which each memory cell is programmed into one of 16 possible threshold voltage levels to encode 4 pages or bits of data. In one example, the four pages can be denoted as LP, UP, XP, and TP (respectively, page0, page1, page2, and page3).

To read the information stored in the QLC, the threshold voltage of the cells that belong to the selected WL are compared against a set of reference read voltages, illustrated in diagram 500 as R1:R15. R1 represents a threshold voltage that can distinguish between L0 and L1. R2 represents a threshold voltage between L1 and L2, and so forth. As an example, cells that are not triggered by R3, but are then triggered by R4 can be understood to have the value at L3. R2 is a higher voltage than R1, R3 is higher than R2, and so forth. The increasing voltage is not illustrated on diagrams below, but will be understood to apply to other voltage distribution diagrams.

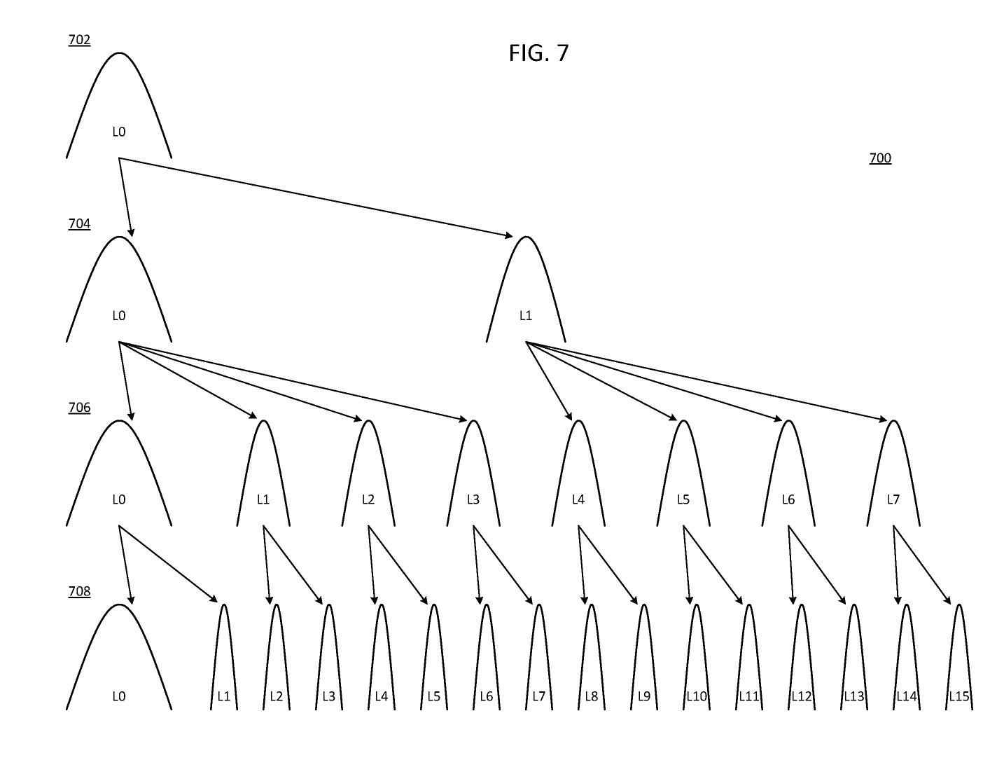

FIG. 6 is a diagram of an example of threshold voltage distribution for QLC cells with a 2-pass 4-16 sequence. Diagram 600 represents a programming sequence for QLC cells. The program sequence of diagram 600 can be applied by a controller that manages the programming of an QLC cell. In one example, the controller performs the sequence of diagram 600 as a default for maximum cell density, and selectively switch to a lower density with fewer bits per cell in a different mode.

Programming the cells in a QLC NAND can be performed in multiple passes as a two-pass 4-16 algorithm. Diagram 600 illustrates an initial (e.g., erased) distribution L0 at stage 602. In the first pass of programming as illustrated at stage 604, the controller provides two pages of data, e.g., LP and UP, and the cells are programmed into one of the four possible states depending on the corresponding LP and UP data. In the second pass as illustrated at stage 606, two more pages of data, e.g., XP and TP, are provided. The controller can read data programmed during the first pass (LP and UP) and program cells into one of 16 possible states.

FIG. 7 is a diagram of an example of threshold voltage distribution for QLC cells with a 3-pass 2-8-16 sequence. Diagram 700 represents a programming sequence for QLC cells. The program sequence of diagram 700 can be applied by a controller that manages the programming of a QLC cell. In one example, the controller performs the sequence of diagram 700 as a default for maximum cell density, and selectively switch to a lower density with fewer bits per cell in a different mode.

Programming the cells in a QLC NAND can be performed in multiple passes as a three-pass 2-8-16 algorithm. Diagram 700 illustrates an initial distribution LO prior to programming at stage 702. In the first pass of programming as illustrated at stage 704, the controller provides one page of data, e.g., LP, into one of the two possible states (L0 or L1) depending on the corresponding LP data. In the second pass as illustrated at stage 706, in one example, two more pages of data, e.g., UP and XP, are provided. In one example of the second pass, the controller reads LP data and programs cells into one of 8 possible states. In one example, in a third pass as illustrated at stage 708, one more page of data, e.g., TP, is provided. In one example of the third pass, the controller reads LP, UP, and XP and programs cells into one of 16 possible states.

In one example, the controller can modify the sequence of diagram 700 by performing all stages of the sequence for a QLC cell, and by not performing the last pass for a TLC cell. In such an example, the storage system can support QLC and TLC with the same program sequence.

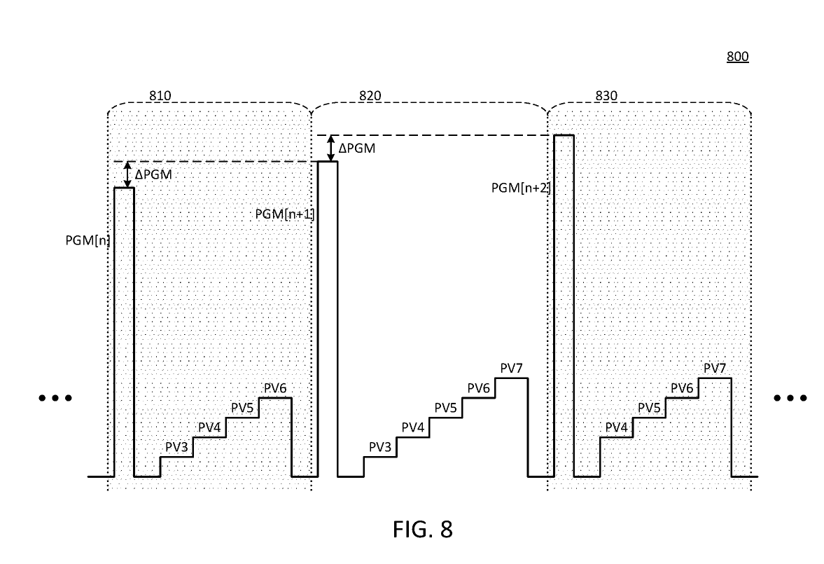

FIG. 8 is a diagram of an example of a program waveform for a QLC NAND. Diagram 800 represents an example of a program waveform for a QLC NAND. Diagram 800 is separated into stage 810, stage 820, and stage 830. In each stage, a program pulse with an amplitude of VPGM is applied, followed by a series of verify operations. The program pulse is then incremented by AVPGM. In a typical sequence, cells that have passed their corresponding verify level are inhibited in the next program pulse.

Memory units with higher number of bits per cell provide higher storage capacity at a given number of cells or addressable storage locations. For example, a QLC NAND offers 33% higher capacity compared to a TLC NAND with the same number of cells. However, the programming speed of a QLC NAND may be approximately four times slower than a comparable TLC NAND.

Diagram 800 illustrates a snapshot of a program sequence where it is assumed that all cells that belong to L1 and L2 have passed the corresponding verify levels PV1 and PV2 and hence are no longer verified. Seeing L1 and L2 have already passed, program verify levels PV3:PV7 are illustrated to perform verification for L3:L7.

Stage 810 illustrates a program pulse PGM[n] with a given amplitude. Assume that the program pulse PGM[n] is not yet high enough to program cells that belong to L7 and above. Stage 820 illustrates a subsequent program pulse PGM[n+1], followed by a series of verify operations. It will be observed that PGM[n+1] is ΔV_{PGM} higher than PGM[1].

Consider the TLC distribution of FIG. 3 and the QLC distribution of FIG. 5. Assuming a comparable programming window for these two distributions, it will be understood that each QLC level should be placed much tighter than similar TLC levels. For example, the difference between the highest verify level (PV7 for TLC or PV15 for QLC) and the lowest read level (R1) suggest closer spacing of each QLC level relative to the TLC levels.

The closer spacing is typically achieved by using a smaller ΔV_{PGM} for QLC than for TLC. For example, ΔV_{PGM} for QLC could be 2× smaller than ΔV_{PGM} for TLC. In one example, a controller with MLC control can program the different delta programming voltages. It will be understood that more pulses may be needed to program cells in QLC compared to TLC. Furthermore, more corresponding verifies would be needed after each program pulse. For example, programming a TLC NAND typically requires two to three verify operations after each program pulse, whereas programming a QLC NAND may require four to five verify pulses after each program pulse. Hence, the total number of verify operations for a QLC NAND is roughly four times higher compared to a typical TLC NAND.

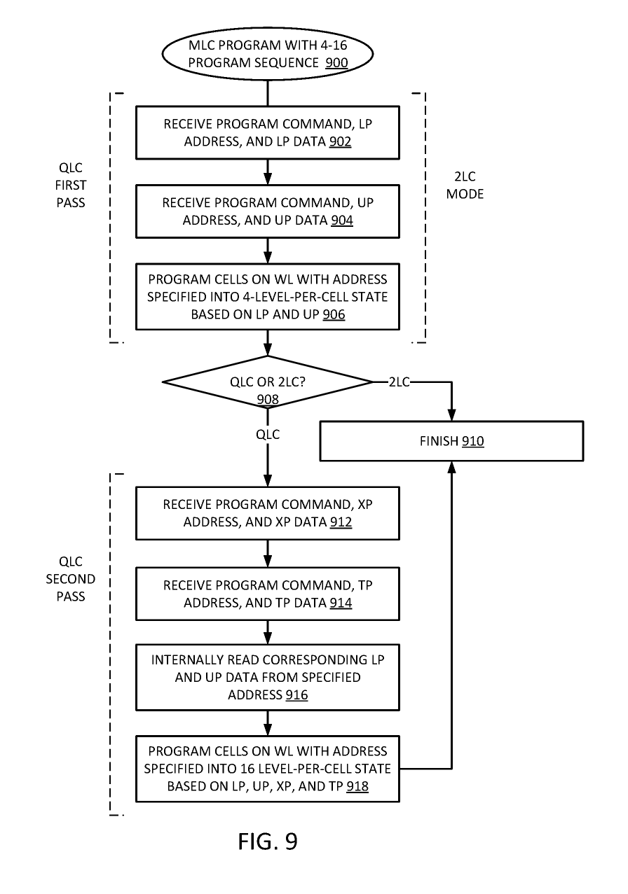

FIG. 9 is a flow diagram of an example of a program process for either QLC or two level cell based on a 4-16 sequence. Process 900 illustrates a program sequence for MLC programming with a 4-16 programming sequence. For process 900, up to 16 states can be based on 4 pages of data, denoted as LP, UP, XP, and TP.

In one example, programming the data in a lower number of bits per cell configuration is achieved by skipping one or more programming passes. For example, a 2-bits-per-cell MLC mode and QLC mode share a common first pass, and the QLC mode has a second pass that can be skipped for a 2-level MLC mode.

In the first pass (the ‘4’ of the program algorithm), in one example, the controller (e.g., a NAND controller) receives a program command, an LP address, and LP data, at 902. The controller receives a program command, a UP address, and UP data, at 904. Thus, the controller receives two pages of data. The controller programs cells on the WL with the address information specified into a 4-level-per-cell state based on LP and UP data, at 906. The distinction between bits and levels will be observed as a 2̂N relationship: a 2-bits-per-cell will be programmed with 4-levels-per-cell (2̂N), and a 4-bits-per-cell will be programmed with 16-levels-per-cell (2̂N), where the programming sets the cell to one or the four states for a 2-bit mode, or one of the 16 states for a 4-bit mode.

If the programming is for a two-bit-per-cell mode (illustrated as 2LC in process 900), at 908 2LC branch, in one example, the controller can skip the second program algorithm pass and finish program, at 910. If the programming is for a QLC mode, at 908 QLC branch, the controller can proceed to the second pass (the ‘16’ of the program algorithm) of the program algorithm. It will be understood that a 4-16 programming algorithm can be reconfigured to operate in a 2-bit-per-cell mode or in the standard mode for higher density. In one example, the controller shares the same program voltage and program verifies for the first pass of the QLC programming algorithm and the 2LC mode of operation.

In one example, in the second pass, the controller receives a program command, XP address, and XP data, at 912. The controller also receives a program command, TP address, and TP data, at 914. In one example, the controller internally reads the corresponding LP and UP data from the specified address, at 916. The controller can then program the cells on the WL with the address specified into one of 16 level-per-cell state based on LP, UP, XP, and TP, at 918.

In one example, the controller applies specific read references for the 2LC mode that may be different that those used to read locations in a QLC mode that have not gone through the second pass of programming (e.g., the last WL of a partially programmed QLC block). In one example, the controller shares the same read references for the 2LC blocks and locations in the QLC blocks that are still in the 4-level state. The controller can maintain an address lookup table to map the address at which data is stored and skip any physical address that corresponds to an XP or TP page inside the QLC. In one example, storage devices still follow the default QLC page order. In one example, the controller does not perform the second pass of programming, since the storage devices do not receive a program command that corresponds to an XP and TP address and finish programming, at 910.

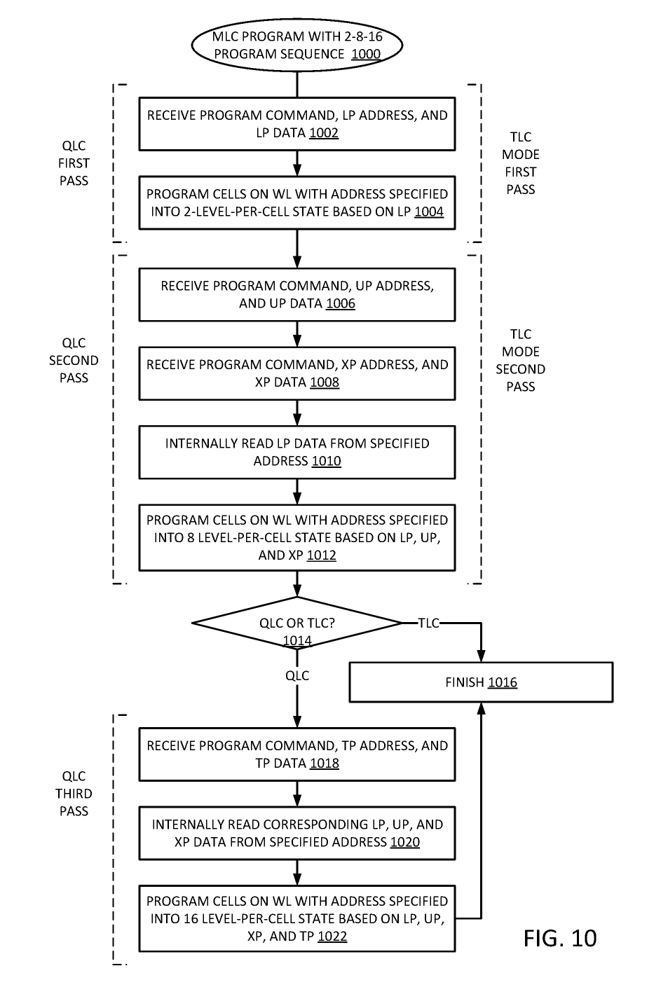

FIG. 10 is a flow diagram of an example of a process to program either QLC or TLC based on a 2-8-16 programming sequence. Process 1000 illustrates a program sequence for MLC programming with a 2-8-16 process. For process 1000, up to 16 states can be based on 4 pages of data, denoted as LP, UP, XP, and TP. For such an implementation, the 2 states would be based on LP, and 8 states would be based on LP, UP, and XP.

In the first pass (the ‘2’ of the program algorithm), in one example, the controller (e.g., a NAND controller) receives a program command, an LP address, and LP data, at 1002. The first pass can be shared between the QLC mode and the TLC mode. In one example, the controller programs cells on the WL with the address specified into 2-level-per-cell state based on LP, at 1004.

In the second pass (the ‘8’ of the program algorithm), in one example, the controller receives a program command, a UP address, and UP data, at 1006. In one example, the controller receives a program command, XP address, and XP data, at 1008. Thus, the controller receives two more pages of data. In one example, the controller internally reads the corresponding LP data from the specified address, at 1010. The controller programs cells on the WL with the address information specified into an 8-level-per-cell state based on LP, UP, and XP data, at 1012.

If the programming is for TLC, at 1014 TLC branch, in one example, the controller can skip the third program algorithm pass and finish programming, at 1016. If the programming is for a QLC mode, at 1014 QLC branch, the controller can proceed to the third pass (the ‘16’ of the program algorithm) of the program algorithm. It will be understood that a 2-8-16 programming algorithm can be reconfigured to operate in a 3-bit-per-cell mode or in the standard mode for higher density. In one example, the controller shares the same program voltage and program verifies for the first pass of the QLC programming algorithm and the TLC mode of operation.

In one example, the controller receives a program command, TP address, and TP data, at 1018. In one example, the controller internally reads the corresponding LP, UP, and XP data from the specified address, at 1020. The controller can then program the cells on the WL with the address specified into one of 16 level-per-cell state based on LP, UP, XP, and TP, at 1022, and finish programming, at 1016.

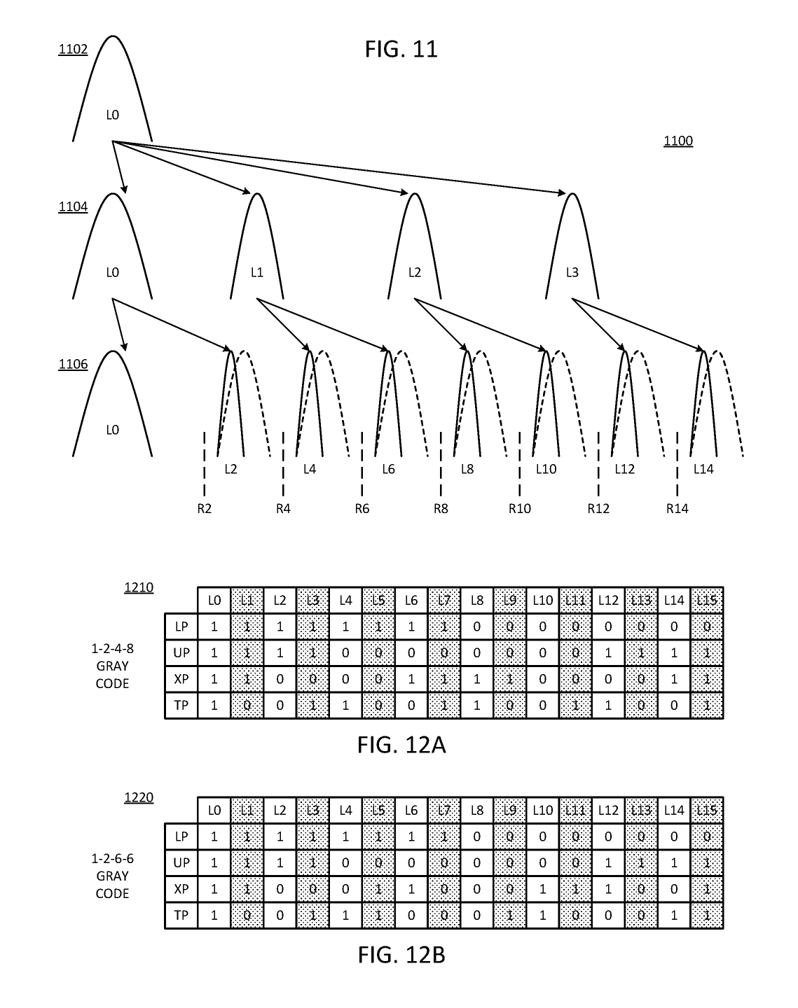

FIG. 11 is a diagram of an example of threshold voltage distribution for a 4-8 programming sequence of TLC cells based on a 4-16 program sequence for QLC cells. Diagram 1100 represents a programming sequence for QLC cells. The program sequence of diagram 1100 can be applied by a controller that manages the programming of QLC cells. In one example, the controller performs the sequence of diagram 1100 as a default for maximum cell density, and selectively switch to a lower density with fewer bits per cell in a different mode.

Programming the cells in a QLC NAND can be performed in multiple passes as a two-pass 4-16 algorithm. Diagram 1100 illustrates an initial threshold voltage distribution LO prior to programming at stage 1102. In the first pass of programming as illustrated at stage 1104, the controller provides two pages of data, e.g., LP and UP, and cells are programmed into one of the four possible states depending on the corresponding LP and UP data. In the second pass as illustrated at stage 1106, two more pages of data, e.g., XP and TP, are provided. The controller can read data programmed during the first pass (LP and UP) and program cells into one of 16 possible states.

The solid line in stage 1106 illustrates the normal threshold voltage distribution for the even states of diagram 1100. Diagram 1100 illustrates a modification of 4-16 QLC programming to achieve 4-8 TLC programming. As illustrated, the first pass represented in stage 1104 remains unchanged, while the second pass can be modified to generate only even levels. LP, UP, and XP data can be read by comparing the threshold voltage of the cells against only even read reference levels, R2:R14.

It will be understood that modification of the last programming stage can leave out odd levels of the programming and the controller can make the distribution for each voltage level broader. The solid line curves represent the distribution for the even numbered voltage levels. The solid lines curves would apply when the programming procedure is applied for a QLC mode. The dashed line curves would apply when the programming procedure is applied for a TLC mode, which can be spread because the QLC odd levels do not exist in the TLC mode.

In one example, the system provides two pages of data (LP and UP) and the controller programs cells into one of 4 possible states L0:L3. In one example, the second pass for TLC provides one page of data (XP). In one example, the controller does not wait for a TP page, but rather starts the programming algorithm by first reading the corresponding LP and UP data from the cells. Since the first pass remains unchanged, the sequence to read the LP and UP data can also remain unchanged. It will be understood that for the QLC program, the controller will wait for the TP page. In one example, the controller modifies the data manipulation so only even levels are generated based on LP, UP, and XP data. In one example, the controller adjusts the verify procedure so none of the odd levels are verified.

In one example, the controller starts the second pass QLC programming. Since only half of the levels are generated in the second pass for TLC program, the spacing between neighboring levels is more than what is needed to correctly read the data. To speed up the second pass programming compared to QLC programming, in one example, the controller applies a higher ΔVPGM. The higher delta results in broadening the level distributions shown with dashed lines.

FIG. 12A is a diagram of an example of a 1-2-4-8 Gray code for QLC level assignment. Diagram 1210 illustrates an example of how data manipulation is modified to generate only even levels for a 1-2-4-8 Gray code. Typically, data is assigned to levels through a Gray code where neighboring levels, differ in the data represented by only one page of data. For example, in diagram 1210 the difference between L0 and L1 only corresponds to TP. It will be understood that with the illustrated Gray code, to generate only even levels the algorithm can set TP=XOR(LP, UP, XP) and keep the rest of the data manipulation to generate the levels unchanged.

In one example, with this Gray code, the Gray mapping has only one bit change between adjacent columns. In one example, the controller can read LP data by comparing the threshold voltage of the cells against R8, read UP data by comparing against R4 and R12, and read XP data by comparing against R2, R6, R10, and R12. Thus, the read operation can be the same as in the QLC configuration, but with optional offsets to better center the read levels between the broader level distributions but in the absence of odd levels.

FIG. 12B is a diagram of an example of a 1-2-6-6 Gray code for QLC level assignment. Diagram 1220 illustrates an example of a 1-2-6-6 Grey code that can be used for QLC level assignment as an alternative to diagram 1210. To generate only even levels, the algorithm can set XP =XOR(LP, UP, XP) while keeping the rest of data manipulation same as the underlying QLC program algorithm. Reading LP and UP pages can remain unchanged.

In one example, with this Gray code, the Gray mapping has only one bit change between adjacent columns. In one example, the controller can read LP data by comparing the threshold voltage of the cells against R8, and read UP data by comparing against R4 and R12. With diagram 1220, to read XP data, the controller can compare the threshold voltage of cells against R2, R6, R10, and R14. This is different than the corresponding QLC read algorithm with the 1-2-6-6 Gray code of diagram 1220, where to read the XP data the threshold voltage of the cells is compared against R2, R5, R7, R10, R13, and R15.

It will be observed that the Gray codes in diagrams 1210 and 1220 are different. However, an XOR operation can align the read operations for the controller. An XOR is not the only option that can be used, but another algorithm can be applied to resolve the differences in the codes. With the modifications, the programming algorithm can be executed in the controller as if nothing changes, but the code modifications can result in generation of only half of the levels.

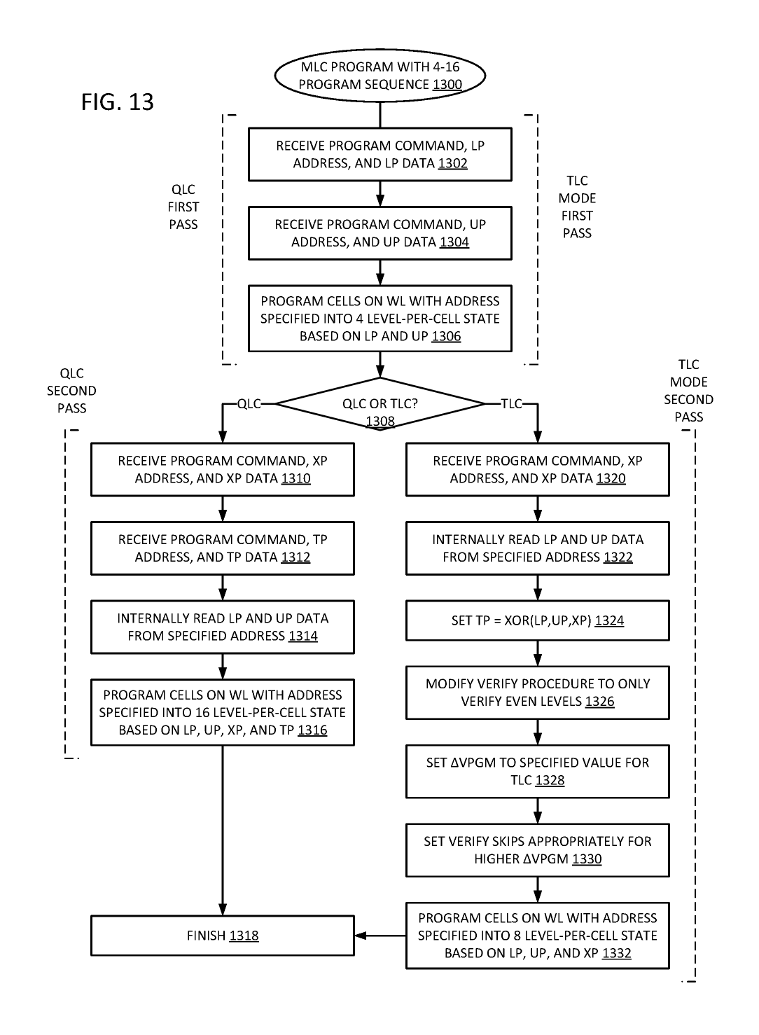

FIG. 13 is a flow diagram of an example of a process to implement either a 4-16 QLC program or 4-8 TLC programming sequence. Process 1300 illustrates a program sequence for MLC programming with a 4-8 or a 4-16 process. More specifically, process 1300 enable the modification of a 4-16 QLC algorithm to a 4-8 TLC algorithm. For process 1300, up to 16 states can be based on 4 pages of data, denoted as LP, UP, XP, and TP. For such an implementation, the 2 states would be based on LP, and 8 states would be based on LP, UP, and XP.

In the first pass (the ‘4’ of the program algorithm), in one example, the controller (e.g., a NAND controller) receives a program command, an LP address, and LP data, at 1302. The first pass can be shared between the QLC mode and the TLC mode. Thus, the program algorithm can be unchanged on the first pass. In one example, the controller receives a program command, a UP address, and UP data, at 1304. In one example, the controller programs cells on the WL with the address specified into 4-level-per-cell state based on LP and UP, at 1306.

In one example, the second pass is different based on whether the controller is to program a QLC or a TLC cell. In one example, to program a QLC, at 1308 QLC branch, the second pass is the ‘16’ of the QLC program algorithm.

In one example, the controller receives a program command, XP address, and XP data, at 1310. In one example, the controller receives a program command, TP address, and TP data, at 1312. Thus, the controller receives two more pages of data. In one example, the controller internally reads the corresponding LP and UP data from the specified address, at 1314. The controller programs cells on the WL with the address information specified into a 16-level-per-cell state based on LP, UP, XP, and TP data, at 1316. The controller can then finish programming, at 1318.

In one example, to program a TLC, at 1308 TLC branch, the second pass is the ‘8’ of the TLC program algorithm. In one example, in the TLC second pass, the controller starts the program algorithm after receiving a program command, address, and data to program an XP page without waiting for TP program command.

Thus, in one example, the controller receives a program command, XP address, and XP data, at 1320. Rather than wait for TP data, the controller can internally read the corresponding LP and UP data from the specified address, at 1322. The controller programs cells on the WL with the address information specified into a 16-level-per-cell state based on LP, UP, XP, and TP data, at 1316. The controller can then finish programming, at 1318.

In one example, the controller sets TP=XOR(LP, UP, XP), at 1324. The controller can modify the verify procedure to only verify even levels, at 1326. In one example, odd levels are not present and therefore there would be no point trying to read them. However, if no change is made, the QLC algorithm would have no knowledge of the lack of odd levels, and would attempt to verify bitlines that correspond to odd levels against their corresponding verify level.

In one example, the controller sets the AVPGM to a specified value for TLC, at 1328. The algorithm may use a specific TLC AVPGM which is higher than the QLC value to speed up the second pass. Since odd levels are absent, the even levels can be made broader than typical QLC levels. In one example, the controller will adjust verify skips appropriately since a higher ΔVPGM is used, at 1330. The controller can then program the cells on the WL with the address specified into one of 8 level-per-cell state based on LP, UP, and XP, at 1332. The controller can then finish programming, at 1318.

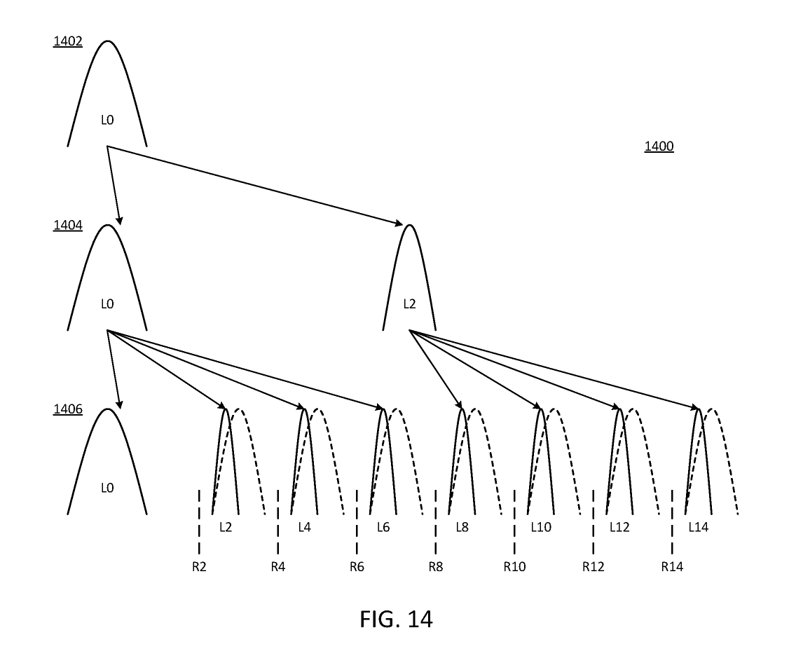

FIG. 14 is a diagram of an example of threshold voltage distribution for a 2-8 program sequence of TLC cells based on a 4-16 program sequence for QLC cells. The first pass of a 4-8 TLC programming algorithm is slower than a 2-8 TLC programming algorithm, whereas a 4-16 QLC programming algorithm is faster than a 2-8-16 QLC algorithm. Thus, instead of performing a 4-8 TLC algorithm as the lower density mode to a 4-16 QLC algorithm, it would be preferable to implement a 2-8 TLC algorithm as a modification of the 4-16 QLC algorithm. Diagram 1400 represents such an implementation.

Diagram 1400 illustrates an initial programming pulse L0 at stage 1402. In the first pass of programming as illustrated at stage 1404, the controller provides a page of data, e.g., LP, into one of the two possible states (L0 and L2) depending on the corresponding LP data. In the second pass as illustrated at stage 1406, two more pages of data, e.g., UP and XP, are provided. The controller can read data programmed during the first pass (LP) and program cells into one of 8 possible states.

The solid line in stage 1106 illustrates the normal pulses for the even states of diagram 1400. Diagram 1400 illustrates a modification of 4-16 QLC programming to achieve 2-8 TLC programming. As illustrated, the first pass represented in stage 1404 can be modified to only generate even levels L0 and L2, while the second pass can be modified to generate only even levels. LP, UP, and XP data can be read by comparing the threshold voltage of the cells against only even read reference levels, R2:R14.

In one example, the controller starts the second pass QLC programming. Since only half of the levels are generated in the second pass for TLC program, the spacing between neighboring levels is more than what is needed to correctly read the data. To speed up the second pass programming compared to QLC programming, in one example, the controller applies a higher ΔVPGM. The higher delta results in broadening the level distributions shown with dashed lines.

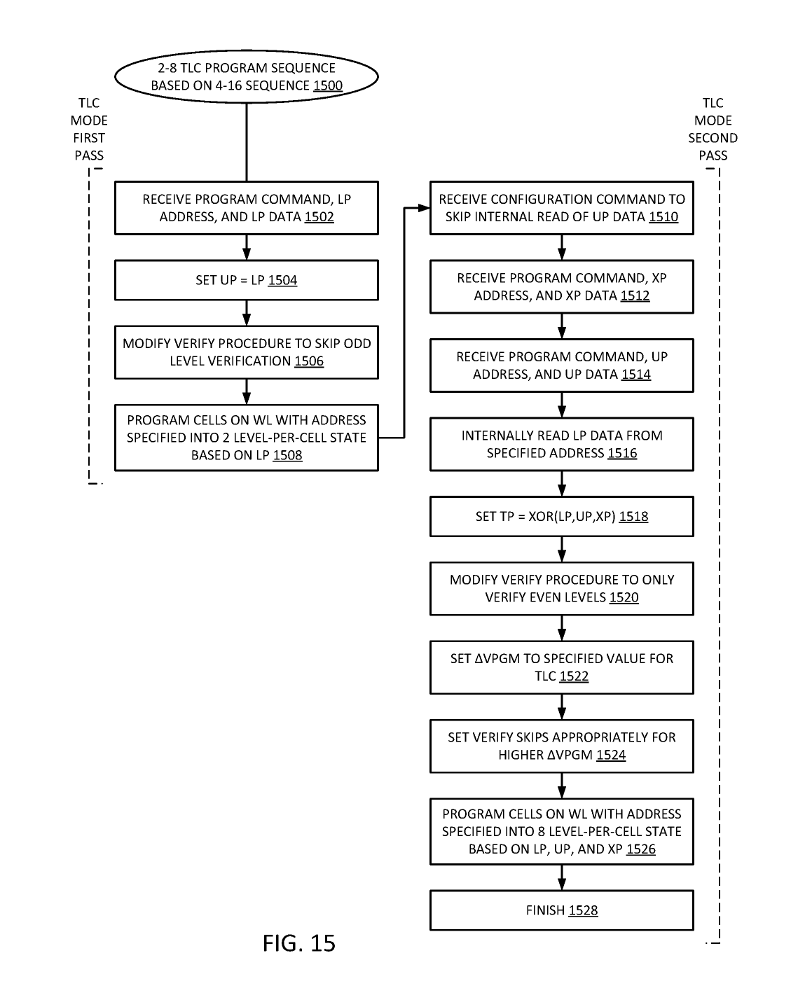

FIG. 15 is a flow diagram of an example of a program process to implement a 2-8 TLC program based on a 4-16 QLC program algorithm. Process 1500 illustrates a possible implementation of a 2-8 TLC algorithm by modifying a 4-16 QLC algorithm. The TLC mode first pass is modified to start the program as soon as program command, address, and data for LP is received.

In one example, the controller (e.g., a NAND controller) receives a program command, an LP address, and LP data, at 1502. To keep the data manipulation to determine level assignments unchanged, in one example, the algorithm sets UP=LP, at 1504. The controller can implement a modified verify procedure to skip odd level verification (L1 and L3), at 1506. In one example, the algorithm proceeds by programming the cells on the WL with the address specified into one of the two possible levels (L0 and L2) based on LP, at 1508.

In a multi-pass programming algorithm, typically the optimum starting program voltage for subsequent passes are calculated based on how the threshold voltage of the cells increase in response to the program voltage in the first pass. The program voltage can be stored to be used during subsequent passes. In a 4-16 QLC programming algorithm, calculation of the optimum program voltage is typically performed based on how L1 cells respond to VPGM. Since no L1 cells exit in the 2-8 TLC mode, in one example, calculation of the optimum start VPGM can be performed based on the response of L2 cells. Alternatively, an erase compaction can be used, where L0 cells are also programmed to a specified PV0. In this case, calculating optimum start VPGM can be performed based on the response of L0 (or all) cells. The optimum start VPGM can be stored in specific locations such as flag bytes of the WL being programmed.

In one example, the TLC mode second pass can be modified relative to the second pass of the QLC algorithm. In one example, the controller is to receive a configuration command to skip internal read of UP data, at 1510. In one example, the controller is to receive UP data externally from the host as opposed to reading UP data internally from the cells that correspond to the specified XP address. Such an operation can be performed when the memory units are reconfigured to operate in the TLC mode, or with a specific reconfiguration command that precedes the second pass.

In one example, the controller (e.g., NAND controller) starts the algorithm after it receives XP and UP program commands, address and data. In one example, the controller receives a program command, XP address, and XP data, at 1512. In one example, the controller receives a program command, UP address, and UP data, at 1514. Thus, the controller receives two more pages of data. In one example, the controller internally reads the corresponding LP data from the specified address, at 1516.

In one example, the controller sets TP=XOR(LP, UP, XP) to avoid changes to data manipulation that determine level assignments, at 1518. In one example, the controller applies a modified verify procedure to only verify even levels; odd levels are not verified, at 1520. In one example, the controller adjusts ΔVPGM to a specified value for TLC, at 1522. In one example, the controller sets verify skips to speed up the second pass, with appropriately higher ΔVPGM, at 1524. The controller can then program the cells on the WL with the address specified into one of 8 level-per-cell state based on LP, UP, and XP, at 1526. The controller can finish programming, at 1528.

Since the final level assignment is based on LP, UP, and XP data, which is same as what is performed with other algorithms for TLC data, the read operation can also same as what was discussed previously. The read operation for Gray coding provided above can apply to read operations as discussed above.

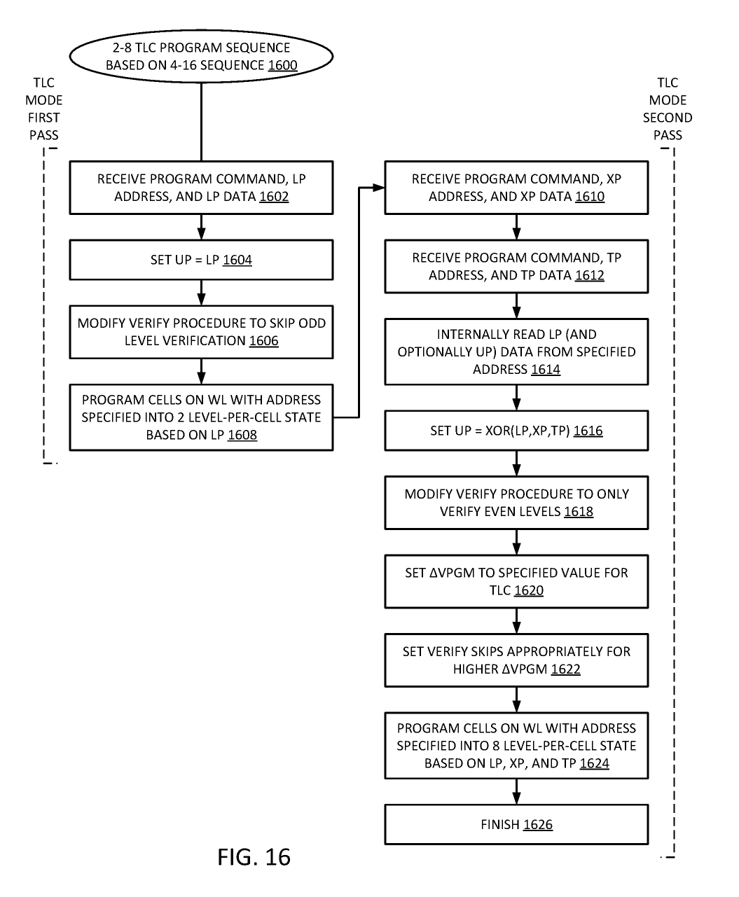

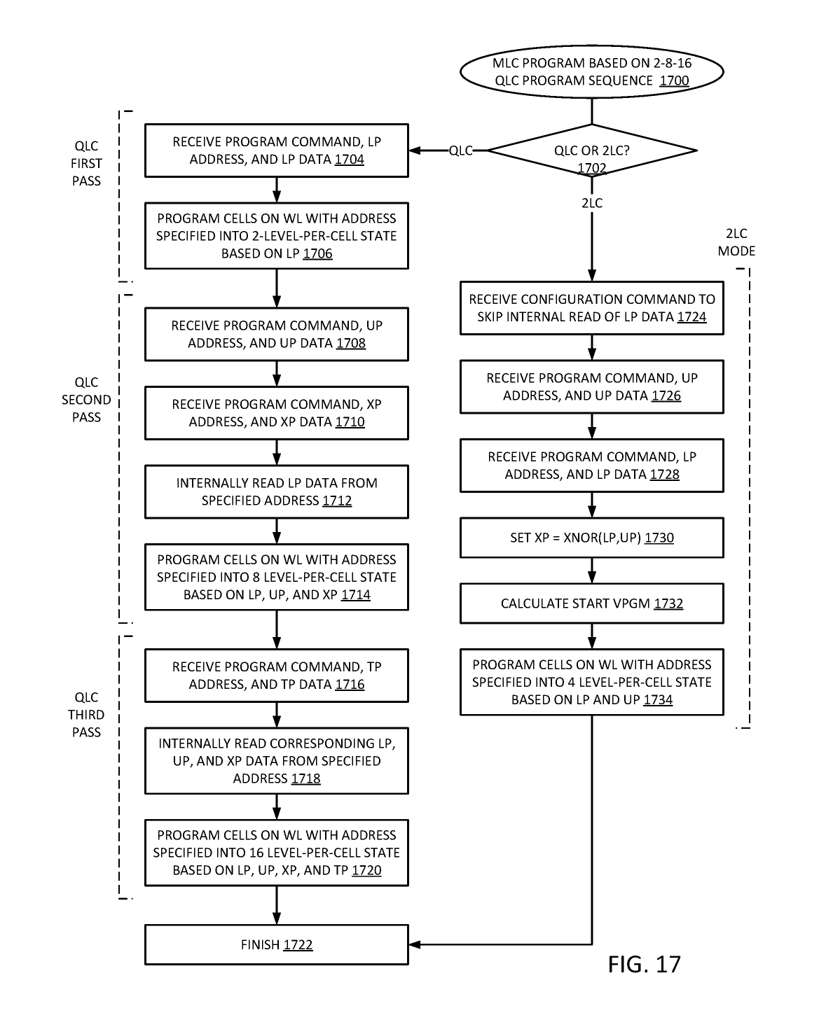

FIG. 16 is a flow diagram of an example of a program process to implement a 2-8 TLC program based on a 4-16 QLC program algorithm as an alternative to FIG. 15. Process 1600 illustrates a possible implementation of a 2-8 TLC algorithm by modifying a 4-16 QLC algorithm. The TLC mode first pass is modified to start the program as soon as program command, address, and data for LP is received.

In one example, the controller (e.g., a NAND controller) receives a program command, an LP address, and LP data, at 1602. To keep the data manipulation to determine level assignments, in one example, the algorithm sets UP=LP, at 1604. The controller can implement a modified verify procedure to skip odd level verification (L1 and L3), at 1606. In one example, the algorithm proceeds by programming the cells on the WL with the address specified into one of the two possible levels (L0 and L2) based on LP, at 1608.

For the TLC mode second pass, in one example, the controller receives a program command, XP address, and XP data, at 1610. In one example, the controller receives a program command, TP address, and TP data, at 1612. Thus, the controller receives two more pages of data. In one example, the controller internally reads the corresponding LP data from the specified address, at 1614. In one example, the controller optionally also reads the UP data from the specified address. Note that since there is no UP data programmed in the first pass, all bits of UP data are read as 1. This value will be overwritten at 1616 as described below.

In one example, the controller sets UP=XOR(LP, XP, TP), at 1616. In one example, the controller applies a modified verify procedure to only verify even levels; odd levels are not verified, at 1618. In one example, the controller adjusts AVPGM to a specified value for TLC, at 1620. In one example, the controller sets verify skips to speed up the second pass, with appropriately higher ΔVPGM, at 1622. The controller can then program the cells on the WL with the address specified into one of 8 level-per-cell state based on LP, XP, and TP, at 1624. The controller can finish programming, at 1626.

In one example, in the second pass, instead of receiving UP data from the host (e.g., from the memory controller or storage controller) and skipping TP data, the TP data is received, and the UP is skipped. In one example, the LP data is read by comparing the threshold voltage of cells against R8 for both Gray codes discussed above. In one example, the read operation for XP remains unchanged compared to the QLC mode, with the Gray code discussed above. With the Gray code, in one example, to read XP data, the threshold voltage of cells is compared to R2, R5, R7, R10, and R13, but with R5, R7, and R13 increased compared to values used in QLC mode.

In one example, the read operation for TP data is also modified. For a 1-2-4-8 Gray code as discussed above, the threshold voltage of cells is compared against R1, R3, R5, R7, R9, R11, R13, and R15 but with these references increased compared to what is used in QLC mode to account for the fact that TLC distributions are broader. One possible setting is to set Ri=Ri+1 for i=1, 3, . . . , 15. Similarly, in one example, the TP read operation for 1-2-6-6 Gray code as discussed above can also be modified. Threshold voltage of cells can be compared against R1, R3, R6, R9, R11, and R14, but with odd reference levels increased compared to the corresponding QLC values. One possible setting is to set Ri=Ri+1 for odd levels.

FIG. 17 is a flow diagram of an example of a program process to implement either a QLC program or a 2LC program based on a 2-8-16 QLC algorithm. Process 1700 illustrates a possible implementation of a 2-8-16 QLC algorithm that could be modified for 2LC programming. For process 1700, up to 16 states can be based on 4 pages of data, denoted as LP, UP, XP, and TP. For such an implementation, the 2 states would be based on LP.

For a QLC programming operation, at 1702 QLC branch, the controller performs a QLC first pass. In the first pass (the ‘2’ of the program algorithm), in one example, the controller (e.g., a NAND controller) receives a program command, an LP address, and LP data, at 1704. In one example, the controller programs cells on the WL with the address specified into 2-level-per-cell state based on LP, at 1706.

In the second pass (the ‘8’ of the program algorithm), in one example, the controller receives a program command, a UP address, and UP data, at 1708. In one example, the controller receives a program command, XP address, and XP data, at 1710. Thus, the controller receives two more pages of data. In one example, the controller internally reads the corresponding LP data from the specified address, at 1712. The controller programs cells on the WL with the address information specified into an 8-level-per-cell state based on LP, UP, and XP data, at 1714.

For the third pass (the ‘16’ of the program algorithm), in one example, the controller receives a program command, TP address, and TP data, at 1716. In one example, the controller internally reads the corresponding LP, UP, and XP data from the specified address, at 1718. The controller can then program the cells on the WL with the address specified into one of 16 level-per-cell state based on LP, UP, XP, and TP, at 1720. The controller can then finish programming, at 1722.

In one example, the 2LC mode skips the first pass of the QLC program process. For a QLC programming operation, at 1702 2LC branch, the controller receives a configuration command to skip internal read of LP data, at 1724. In one example, the controller receives a program command, a UP address, and UP data, at 1726. In one example, the controller receives a program command, an LP address, and LP data, at 1728. In one example, the controller sets XP=XNOR(LP, UP), at 1730. In one example, the controller calculates a start VPGM for the implementation, at 1732. In one example, the controller programs the cells on the WL with the address specified into one of 4 level-per-cell state based on LP and UP, at 1734. The controller can then finish programming, at 1722.

As provided in the above description, the second pass can be modified so the NAND controller does not internally read LP data, and instead receives it from the memory controller. To keep the data manipulation to assign levels, the NAND controller may set XP equal to the XNOR of LP and UP. In one example, the verify procedure is modified to skip odd levels. Since the first pass is skipped, the optimum start VPGM can be calculated instead of reading from flag locations. The third pass of the program algorithm is also skipped.

In one example of a NAND device, different WLs may have different numbers of bits per cell. For example, WLs near the boundary of the block, e.g., near the select transistors, may have a smaller number of bits per cell. For example, in QLC NAND, some WLs may be configured to have 3 bits per cell. When reconfigured to operate in TLC mode, these WLs may be reconfigured to operate at a smaller number of bits per cell, for example, 2 bits per cell. In some example, when reconfigured to operate in TLC modes, these WLs may be configured to maintain their density used in QLC mode.

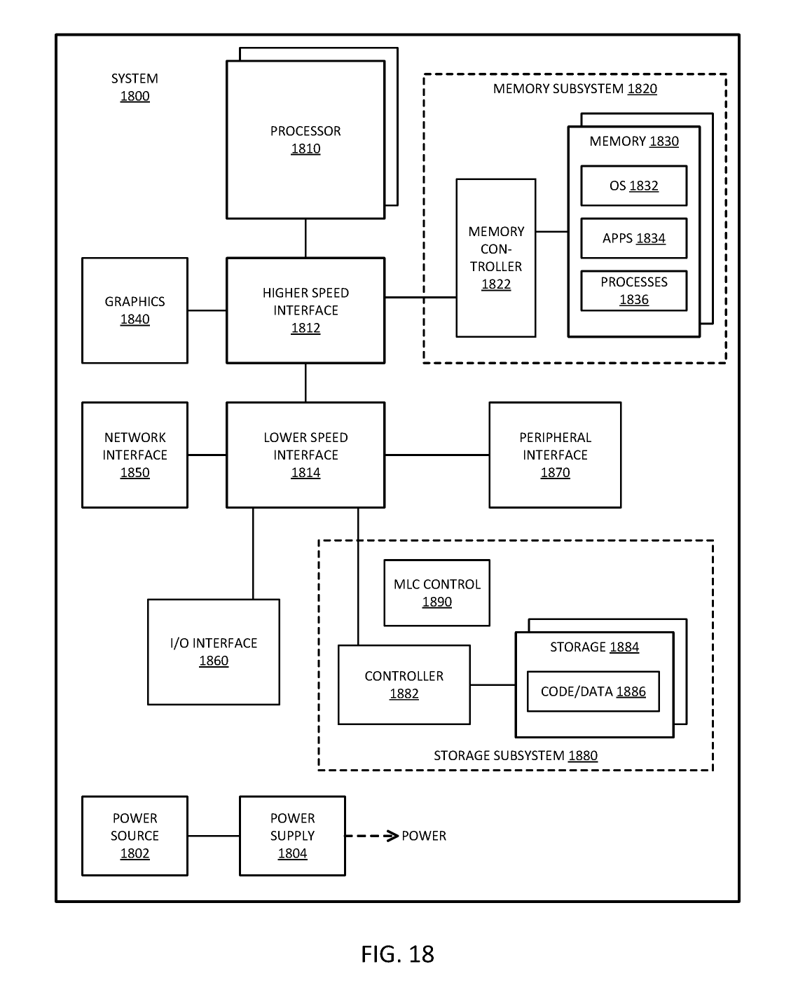

FIG. 18 is a block diagram of an example of a computing system in which a storage device selectively that stores data at either one multilevel cell density or another multilevel cell density can be implemented. System 1800 represents a computing device in accordance with any example herein, and can be a laptop computer, a desktop computer, a tablet computer, a server, a gaming or entertainment control system, embedded computing device, or other electronic device.

System 1800 MLC control 1890 in storage subsystem 1880. MLC control 1890 represents logic to provide dynamically reconfigurable memory cells within storage 1884. The MLC control can perform dynamic reconfiguration in accordance with any example herein. The dynamic reconfiguration enables the controller to provide either higher density or lower density.

System 1800 includes processor 1810 can include any type of microprocessor, central processing unit (CPU), graphics processing unit (GPU), processing core, or other processing hardware, or a combination, to provide processing or execution of instructions for system 1800. Processor 1810 controls the overall operation of system 1800, and can be or include, one or more programmable general-purpose or special-purpose microprocessors, digital signal processors (DSPs), programmable controllers, application specific integrated circuits (ASICs), programmable logic devices (PLDs), or a combination of such devices.

In one example, system 1800 includes interface 1812 coupled to processor 1810, which can represent a higher speed interface or a high throughput interface for system components that need higher bandwidth connections, such as memory subsystem 1820 or graphics interface components 1840. Interface 1812 represents an interface circuit, which can be a standalone component or integrated onto a processor die. Interface 1812 can be integrated as a circuit onto the processor die or integrated as a component on a system on a chip. Where present, graphics interface 1840 interfaces to graphics components for providing a visual display to a user of system 1800. Graphics interface 1840 can be a standalone component or integrated onto the processor die or system on a chip. In one example, graphics interface 1840 can drive a high definition (HD) display that provides an output to a user. In one example, the display can include a touchscreen display. In one example, graphics interface 1840 generates a display based on data stored in memory 1830 or based on operations executed by processor 1810 or both.

Memory subsystem 1820 represents the main memory of system 1800, and provides storage for code to be executed by processor 1810, or data values to be used in executing a routine. Memory subsystem 1820 can include one or more memory devices 1830 such as read-only memory (ROM), flash memory, one or more varieties of random access memory (RAM) such as DRAM, or other memory devices, or a combination of such devices. Memory 1830 stores and hosts, among other things, operating system (OS) 1832 to provide a software platform for execution of instructions in system 1800. Additionally, applications 1834 can execute on the software platform of OS 1832 from memory 1830. Applications 1834 represent programs that have their own operational logic to perform execution of one or more functions. Processes 1836 represent agents or routines that provide auxiliary functions to OS 1832 or one or more applications 1834 or a combination. OS 1832, applications 1834, and processes 1836 provide software logic to provide functions for system 1800. In one example, memory subsystem 1820 includes memory controller 1822, which is a memory controller to generate and issue commands to memory 1830. It will be understood that memory controller 1822 could be a physical part of processor 1810 or a physical part of interface 1812. For example, memory controller 1822 can be an integrated memory controller, integrated onto a circuit with processor 1810, such as integrated onto the processor die or a system on a chip.

While not specifically illustrated, it will be understood that system 1800 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1800 includes interface 1814, which can be coupled to interface 1812. Interface 1814 can be a lower speed interface than interface 1812. In one example, interface 1814 represents an interface circuit, which can include standalone components and integrated circuitry. In one example, multiple user interface components or peripheral components, or both, couple to interface 1814. Network interface 1850 provides system 1800 the ability to communicate with remote devices (e.g., servers or other computing devices) over one or more networks. Network interface 1850 can include an Ethernet adapter, wireless interconnection components, cellular network interconnection components, USB (universal serial bus), or other wired or wireless standards-based or proprietary interfaces. Network interface 1850 can exchange data with a remote device, which can include sending data stored in memory or receiving data to be stored in memory.

In one example, system 1800 includes one or more input/output (I/O) interface(s) 1860. I/O interface 1860 can include one or more interface components through which a user interacts with system 1800 (e.g., audio, alphanumeric, tactile/touch, or other interfacing). Peripheral interface 1870 can include any hardware interface not specifically mentioned above. Peripherals refer generally to devices that connect dependently to system 1800. A dependent connection is one where system 1800 provides the software platform or hardware platform or both on which operation executes, and with which a user interacts.

In one example, system 1800 includes storage subsystem 1880 to store data in a nonvolatile manner. In one example, in certain system implementations, at least certain components of storage 1880 can overlap with components of memory subsystem 1820. Storage subsystem 1880 includes storage device(s) 1884, which can be or include any conventional medium for storing large amounts of data in a nonvolatile manner, such as one or more magnetic, solid state, or optical based disks, or a combination. Storage 1884 holds code or instructions and data 1886 in a persistent state (i.e., the value is retained despite interruption of power to system 1800). Storage 1884 can be generically considered to be a “memory, ” although memory 1830 is typically the executing or operating memory to provide instructions to processor 1810. Whereas storage 1884 is nonvolatile, memory 1830 can include volatile memory (i.e., the value or state of the data is indeterminate if power is interrupted to system 1800). In one example, storage subsystem 1880 includes controller 1882 to interface with storage 1884. In one example controller 1882 is a physical part of interface 1814 or processor 1810, or can include circuits or logic in both processor 1810 and interface 1814.

Power source 1802 provides power to the components of system 1800. More specifically, power source 1802 typically interfaces to one or multiple power supplies 1804 in system 1800 to provide power to the components of system 1800. In one example, power supply 1804 includes an AC to DC (alternating current to direct current) adapter to plug into a wall outlet. Such AC power can be renewable energy (e.g., solar power) power source 1802. In one example, power source 1802 includes a DC power source, such as an external AC to DC converter. In one example, power source 1802 or power supply 1804 includes wireless charging hardware to charge via proximity to a charging field. In one example, power source 1802 can include an internal battery or fuel cell source.

Reference to storage devices can refer to a nonvolatile memory device whose state is determinate even if power is interrupted to the device. In one example, the nonvolatile memory device is a block addressable memory device, such as NAND or NOR technologies. Thus, a memory device can also include a future generation nonvolatile devices, such as a three dimensional crosspoint memory device, other byte addressable nonvolatile memory devices, or memory devices that use chalcogenide phase change material (e.g., chalcogenide glass). In one example, the memory device can be or include multi-threshold level NAND flash memory, NOR flash memory, single or multi-level phase change memory (PCM) or phase change memory with a switch (PCMS), a resistive memory, nanowire memory, ferroelectric transistor random access memory (FeTRAM), magnetoresistive random access memory (MRAM) memory that incorporates memristor technology, or spin transfer torque (STT)-MRAM, or a combination of any of the above, or other memory.

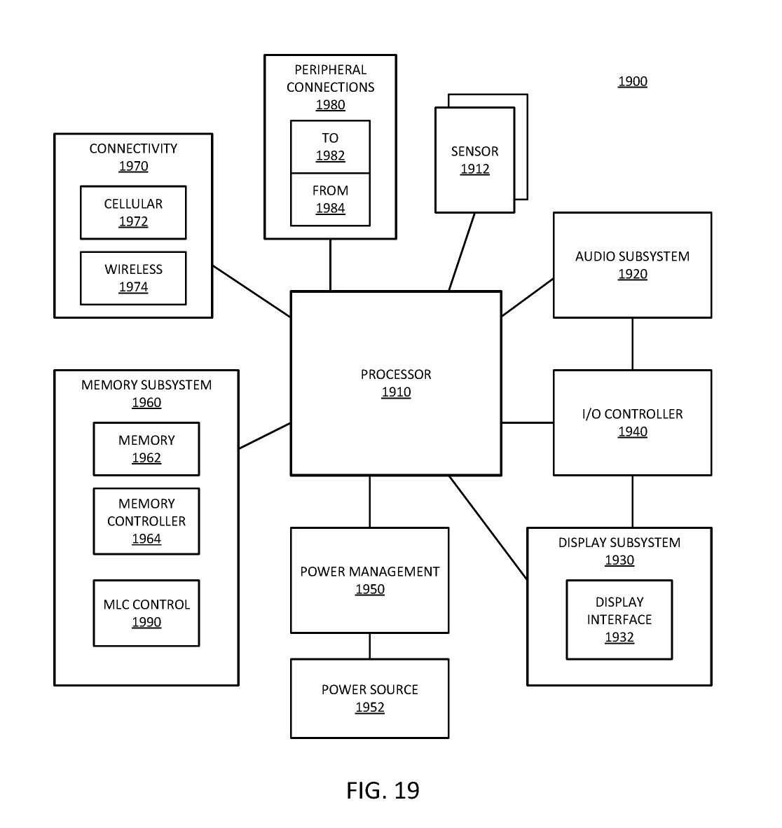

FIG. 19 is a block diagram of an example of a mobile device in which a storage device selectively that stores data at either one multilevel cell density or another multilevel cell density can be implemented. System 1900 represents a mobile computing device, such as a computing tablet, a mobile phone or smartphone, wearable computing device, or other mobile device, or an embedded computing device. It will be understood that certain of the components are shown generally, and not all components of such a device are shown in system 1900.

System 1900 MLC control 1990 in nonvolatile storage of memory subsystem 1960. MLC control 1990 represents logic to provide dynamically reconfigurable memory cells within nonvolatile storage of memory 1962. The MLC control can perform dynamic reconfiguration in accordance with any example herein. The dynamic reconfiguration enables the controller to provide either higher density or lower density.

System 1900 includes processor 1910, which performs the primary processing operations of system 1900. Processor 1910 can include one or more physical devices, such as microprocessors, application processors, microcontrollers, programmable logic devices, or other processing means. The processing operations performed by processor 1910 include the execution of an operating platform or operating system on which applications and device functions are executed. The processing operations include operations related to I/O (input/output) with a human user or with other devices, operations related to power management, operations related to connecting system 1900 to another device, or a combination. The processing operations can also include operations related to audio I/O, display I/O, or other interfacing, or a combination. Processor 1910 can execute data stored in memory. Processor 1910 can write or edit data stored in memory.

In one example, system 1900 includes one or more sensors 1912. Sensors 1912 represent embedded sensors or interfaces to external sensors, or a combination. Sensors 1912 enable system 1900 to monitor or detect one or more conditions of an environment or a device in which system 1900 is implemented. Sensors 1912 can include environmental sensors (such as temperature sensors, motion detectors, light detectors, cameras, chemical sensors (e.g., carbon monoxide, carbon dioxide, or other chemical sensors)), pressure sensors, accelerometers, gyroscopes, medical or physiology sensors (e.g., biosensors, heart rate monitors, or other sensors to detect physiological attributes), or other sensors, or a combination. Sensors 1912 can also include sensors for biometric systems such as fingerprint recognition systems, face detection or recognition systems, or other systems that detect or recognize user features. Sensors 1912 should be understood broadly, and not limiting on the many different types of sensors that could be implemented with system 1900. In one example, one or more sensors 1912 couples to processor 1910 via a frontend circuit integrated with processor 1910. In one example, one or more sensors 1912 couples to processor 1910 via another component of system 1900.

In one example, system 1900 includes audio subsystem 1920, which represents hardware (e.g., audio hardware and audio circuits) and software (e.g., drivers, codecs) components associated with providing audio functions to the computing device. Audio functions can include speaker or headphone output, as well as microphone input. Devices for such functions can be integrated into system 1900, or connected to system 1900. In one example, a user interacts with system 1900 by providing audio commands that are received and processed by processor 1910.

Display subsystem 1930 represents hardware (e.g., display devices) and software components (e.g., drivers) that provide a visual display for presentation to a user. In one example, the display includes tactile components or touchscreen elements for a user to interact with the computing device. Display subsystem 1930 includes display interface 1932, which includes the particular screen or hardware device used to provide a display to a user. In one example, display interface 1932 includes logic separate from processor 1910 (such as a graphics processor) to perform at least some processing related to the display. In one example, display subsystem 1930 includes a touchscreen device that provides both output and input to a user. In one example, display subsystem 1930 includes a high definition (HD) or ultra-high definition (UHD) display that provides an output to a user. In one example, display subsystem includes or drives a touchscreen display. In one example, display subsystem 1930 generates display information based on data stored in memory or based on operations executed by processor 1910 or both.

I/O controller 1940 represents hardware devices and software components related to interaction with a user. I/O controller 1940 can operate to manage hardware that is part of audio subsystem 1920, or display subsystem 1930, or both. Additionally, I/O controller 1940 illustrates a connection point for additional devices that connect to system 1900 through which a user might interact with the system. For example, devices that can be attached to system 1900 might include microphone devices, speaker or stereo systems, video systems or other display device, keyboard or keypad devices, or other I/O devices for use with specific applications such as card readers or other devices.

As mentioned above, I/O controller 1940 can interact with audio subsystem 1920 or display subsystem 1930 or both. For example, input through a microphone or other audio device can provide input or commands for one or more applications or functions of system 1900. Additionally, audio output can be provided instead of or in addition to display output. In another example, if display subsystem includes a touchscreen, the display device also acts as an input device, which can be at least partially managed by I/O controller 1940. There can also be additional buttons or switches on system 1900 to provide I/O functions managed by I/O controller 1940.

In one example, I/O controller 1940 manages devices such as accelerometers, cameras, light sensors or other environmental sensors, gyroscopes, global positioning system (GPS), or other hardware that can be included in system 1900, or sensors 1912. The input can be part of direct user interaction, as well as providing environmental input to the system to influence its operations (such as filtering for noise, adjusting displays for brightness detection, applying a flash for a camera, or other features).

In one example, system 1900 includes power management 1950 that manages battery power usage, charging of the battery, and features related to power saving operation. Power management 1950 manages power from power source 1952, which provides power to the components of system 1900. In one example, power source 1952 includes an AC to DC (alternating current to direct current) adapter to plug into a wall outlet. Such AC power can be renewable energy (e.g., solar power, motion based power). In one example, power source 1952 includes only DC power, which can be provided by a DC power source, such as an external AC to DC converter. In one example, power source 1952 includes wireless charging hardware to charge via proximity to a charging field. In one example, power source 1952 can include an internal battery or fuel cell source.

Memory subsystem 1960 includes memory device(s) 1962 for storing information in system 1900. Memory subsystem 1960 can include nonvolatile (state does not change if power to the memory device is interrupted) or volatile (state is indeterminate if power to the memory device is interrupted) memory devices, or a combination. Memory 1960 can store application data, user data, music, photos, documents, or other data, as well as system data (whether long-term or temporary) related to the execution of the applications and functions of system 1900. In one example, memory subsystem 1960 includes memory controller 1964 (which could also be considered part of the control of system 1900, and could potentially be considered part of processor 1910). Memory controller 1964 includes a scheduler to generate and issue commands to control access to memory device 1962.

Connectivity 1970 includes hardware devices (e.g., wireless or wired connectors and communication hardware, or a combination of wired and wireless hardware) and software components (e.g., drivers, protocol stacks) to enable system 1900 to communicate with external devices. The external device could be separate devices, such as other computing devices, wireless access points or base stations, as well as peripherals such as headsets, printers, or other devices. In one example, system 1900 exchanges data with an external device for storage in memory or for display on a display device. The exchanged data can include data to be stored in memory, or data already stored in memory, to read, write, or edit data.

Connectivity 1970 can include multiple different types of connectivity. To generalize, system 1900 is illustrated with cellular connectivity 1972 and wireless connectivity 1974. Cellular connectivity 1972 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, LTE (long term evolution—also referred to as “4G”), or other cellular service standards. Wireless connectivity 1974 refers to wireless connectivity that is not cellular, and can include personal area networks (such as Bluetooth), local area networks (such as WiFi), or wide area networks (such as WiMax), or other wireless communication, or a combination. Wireless communication refers to transfer of data through the use of modulated electromagnetic radiation through a non-solid medium. Wired communication occurs through a solid communication medium.

Peripheral connections 1980 include hardware interfaces and connectors, as well as software components (e.g., drivers, protocol stacks) to make peripheral connections. It will be understood that system 1900 could both be a peripheral device (“to” 1982) to other computing devices, as well as have peripheral devices (“from” 1984) connected to it. Device 1900 commonly has a “docking” connector to connect to other computing devices for purposes such as managing (e.g., downloading, uploading, changing, synchronizing) content on system 1900. Additionally, a docking connector can allow system 1900 to connect to certain peripherals that allow system 1900 to control content output, for example, to audiovisual or other systems.

In addition to a proprietary docking connector or other proprietary connection hardware, system 1900 can make peripheral connections 1980 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), or other type.

In general, with respect to the descriptions herein, in one example a memory device includes: an array of multilevel storage cells (MLC storage cells); and a controller to selectively write to MLC storage cells at a first MLC density or a second MLC density lower than the first MLC density.

In one example, the first MLC density comprises quad level storage cells (QLC storage cells). In one example, the second MLC density comprises trilevel storage cells (TLC storage cells) or double level storage cells. In one example, the storage cells comprise NAND (not AND) storage cells. In one example, the controller is to program both the storage cells of the first MLC density and the second MLC density with a common programming process. In one example, the controller is to skip a step of the common programming process. In one example, the controller is to modify a final step of the common programming process to write less data for the second MLC density. In one example, the controller is to selectively write to the MLC storage cells at the second MLC density in response to detection of an increased write throughput to the memory device. In one example, in response to detection that write throughput has slowed, the controller is to store data from the MLC storage cells at the second MLC density to MLC storage cells at the first MLC density.

In general with respect to the descriptions herein, in one example a system includes: a storage controller; and a nonvolatile storage device coupled to the storage controller, the storage device including an array of multilevel storage cells (MLC storage cells); and a controller to selectively write to MLC storage cells at a first MLC density or a second MLC density lower than the first MLC density.

In one example, the first MLC density comprises quad level storage cells (QLC storage cells). In one example, the second MLC density comprises trilevel storage cells (TLC storage cells) or double level storage cells. In one example, the storage cells comprise NAND (not AND) storage cells. In one example, the controller is to program both the storage cells of the first MLC density and the second MLC density with a common programming process. In one example, the controller is to skip a step of the common programming process. In one example, the controller is to modify a final step of the common programming process to write less data for the second MLC density. In one example, the controller is to selectively write to the MLC storage cells at the second MLC density in response to detection of an increased write throughput to the memory device. In one example, in response to detection that write throughput has slowed, the controller is to store data from the MLC storage cells at the second MLC density to MLC storage cells at the first MLC density. In one example, the system includes one or more of: a host processor device coupled to the storage controller; a display communicatively coupled to a host processor; a network interface communicatively coupled to a host processor; or a battery to power the system.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A memory device, comprising:
an array of multilevel storage cells (MLC storage cells); and
a controller to selectively write to MLC storage cells at a first MLC density or a second MLC density lower than the first MLC density.

2. The memory device of claim 1, wherein the first MLC density comprises quad level storage cells (QLC storage cells).

3. The memory device of claim 2, wherein the second MLC density comprises trilevel storage cells (TLC storage cells) or double level storage cells.

4. The memory device of claim 1, wherein the storage cells comprise NAND (not AND) storage cells.

5. The memory device of claim 1, wherein the controller is to program both the storage cells of the first MLC density and the second MLC density with a common programming process.

6. The memory device of claim 5, wherein the controller is to skip a step of the common programming process.

7. The memory device of claim 5, wherein the controller is to modify a final step of the common programming process to write less data for the second MLC density.

8. The memory device of claim 1, wherein the controller is to selectively write to the MLC storage cells at the second MLC density in response to detection of an increased write throughput to the memory device.

9. The memory device of claim 8, wherein in response to detection that write throughput has slowed, the controller is to store data from the MLC storage cells at the second MLC density to MLC storage cells at the first MLC density.

10. A system, comprising:
a storage controller; and
a nonvolatile storage device coupled to the storage controller, the storage device including
an array of multilevel storage cells (MLC storage cells); and
a controller to selectively write to MLC storage cells at a first MLC density or a second MLC density lower than the first MLC density.

11. The system of claim 10, wherein the first MLC density comprises quad level storage cells (QLC storage cells).

12. The system of claim 11, wherein the second MLC density comprises trilevel storage cells (TLC storage cells) or double level storage cells.

13. The system of claim 10, wherein the storage cells comprise NAND (not AND) storage cells.

14. The system of claim 10, wherein the controller is to program both the storage cells of the first MLC density and the second MLC density with a common programming process.

15. The system of claim 14, wherein the controller is to skip a step of the common programming process.

16. The system of claim 14, wherein the controller is to modify a final step of the common programming process to write less data for the second MLC density.

17. The system of claim 10, wherein the controller is to selectively write to the MLC storage cells at the second MLC density in response to detection of an increased write throughput to the storage device.

18. The system of claim 17, wherein in response to detection that write throughput has slowed, the controller is to store data from the MLC storage cells at the second MLC density to MLC storage cells at the first MLC density.

19. The system of claim 10, further comprising one or more of:
a host processor device coupled to the storage controller;
a display communicatively coupled to a host processor;
a network interface communicatively coupled to a host processor; or
a battery to power the system.
